(19) United States
(12) Patent Application Publication
(10) Pub. No.: US 2020/0091236 A1
(43) Pub. Date: Mar. 19, 2020

(54) SEMICONDUCTOR MEMORY DEVICE

(71) Applicant: Toshiba Memory Corporation, Tokyo (JP)

(72) Inventors: Akira HOKAZONO, Kawasaki Kanagawa (JP); Hitoshi IWAI, Kamakura Kanagawa (JP)

(73) Assignee: Toshiba Memory Corporation, Tokyo (JP)

(21) Appl. No.: 16/267,903

(22) Filed: Feb. 5, 2019

(30) Foreign Application Priority Data
Sep. 18, 2018 (JP) P2018-173729

(51) Int. Cl. H01L 27/24; G11C 13/00

(52) U.S. Cl. CPC H01L 27/2454; H01L 27/2409; G11C 13/0069; G11C 13/003; G11C 2213/72; G11C 2213/79; G11C 13/004

(57) ABSTRACT

A semiconductor memory device includes a substrate, a plurality of first wirings arranged in a first direction, a second wiring extending in the first direction, a resistance change film provided between the first wiring and the second wiring, a third wiring which extends in the second direction, a first semiconductor layer connected to the second wiring and the third wiring, a first electrode, a fourth wiring connected to the second wiring, and extends in the third direction, a fifth wiring provided between the fourth wiring and the substrate, extending in the first direction, and connected to the fourth wiring, a sixth wiring provided between the fifth wiring and the substrate, a second semiconductor layer provided between the fifth wiring and the sixth wiring and connected to the fifth wiring and the sixth wiring, and a second electrode.

### CROSS-REFERENCE TO RELATED APPLICATION

This application claims the benefit of and priority to Japanese Patent Application No. 2018-173729, filed Sep. 18, 2018, the entire contents of which are incorporated herein by reference.

### FIELD

Embodiments described herein relate generally to a semiconductor memory device.

### BACKGROUND

Along with high integration of a semiconductor memory device, development of a semiconductor memory device in which memory cells are three-dimensionally arranged progresses. For such a semiconductor memory device, for example, a so-called resistive random-access memory (ReRAM) memory cell that uses a variable resistance element that reversibly changes a resistance value, a so-called flash memory that uses a field effect transistor that may store electric charges in a gate insulation layer as a memory cell, and the like may be used.

### DESCRIPTION OF THE DRAWINGS

FIG. 1 is a schematic circuit diagram illustrating a configuration of a semiconductor memory device including a first memory cell array MA1, according to some embodiments.

FIG. 2 is a schematic circuit diagram illustrating a configuration of a semiconductor memory device according to a comparative example.

FIG. 3 is a schematic perspective view illustrating an aspect of the configuration illustrated in FIG. 1, according to some embodiments.

FIG. 4 is a schematic perspective view illustrating a manufacturing method of the configuration illustrated in FIG. 3, according to some embodiments.

FIG. 5 is a schematic perspective view illustrating the manufacturing method, according to some embodiments.

FIG. 6 is another schematic perspective view illustrating the manufacturing method, according to some embodiments.

FIG. 7 is still another schematic perspective view illustrating the manufacturing method, according to some embodiments.

FIG. 8 is still another schematic perspective view illustrating the manufacturing method, according to some embodiments.

FIG. 9 is still another schematic perspective view illustrating the manufacturing method, according to some embodiments.

FIG. 10 is still another schematic perspective view illustrating the manufacturing method, according to some embodiments.

FIG. 11 is still another schematic perspective view illustrating the manufacturing method, according to some embodiments.

FIG. 12 is still another schematic perspective view illustrating the manufacturing method, according to some embodiments.

FIG. 13 is still another schematic perspective view illustrating the manufacturing method, according to some embodiments.

FIG. 14 is still another schematic perspective view illustrating the manufacturing method, according to some embodiments.

FIG. 15 is a schematic perspective view illustrating a configuration of a semiconductor memory device according to a comparative example.

FIG. 16 is a schematic circuit diagram illustrating a configuration of a semiconductor memory device including a second memory cell array MA2, according to some embodiments.

FIG. 17 is a schematic perspective view illustrating one aspect of the configuration illustrated in FIG. 16, according to some embodiments.

FIG. 18 is a schematic perspective view illustrating a manufacturing method of the configuration illustrated in FIG. 17, according to some embodiments.

FIG. 19 is another schematic perspective view illustrating the manufacturing method, according to some embodiments.

FIG. 20 is still another schematic perspective view illustrating the manufacturing method, according to some embodiments.

FIG. 21 is still another schematic perspective view illustrating the manufacturing method, according to some embodiments.

FIG. 22 is still another schematic perspective view illustrating the manufacturing method, according to some embodiments.

FIG. 23 is still another schematic perspective view illustrating the manufacturing method, according to some embodiments.

FIG. 24 is still another schematic perspective view illustrating the manufacturing method, according to some embodiments.

FIG. 25 is still another schematic perspective view illustrating the manufacturing method, according to some embodiments.

FIG. 26 is a schematic plan view illustrating a layout on a substrate, according to some embodiments.

FIG. 27 is a schematic enlarged view of a region indicated by A in FIG. 26, according to some embodiments.

FIG. 28 is a schematic circuit diagram illustrating a model used for simulation of an operating voltage, according to some embodiments.

FIG. 29 is another schematic circuit diagram illustrating a model used for simulation of an operating voltage, according to some embodiments.

FIG. 30 is a schematic graph illustrating a result of the simulation, according to some embodiments.

FIG. 31 is a schematic circuit diagram illustrating a circuit, according to some embodiments.

FIG. 32 is a schematic graph illustrating an operating voltage of the circuit, according to some embodiments.

FIG. 33 is a schematic circuit diagram illustrating a model used for simulation of an operating voltage, according to some embodiments.

FIG. 34 is a schematic graph illustrating a result of the simulation, according to some embodiments.

FIG. 35 is a schematic graph illustrating an operating voltage, according to some embodiments.

### DETAILED DESCRIPTION

Embodiments described herein provide for a semiconductor memory device which operates stably.

In general, according to one embodiment, a semiconductor memory device includes a substrate, a plurality of first wirings arranged in a first direction intersecting with a surface of the substrate, a second wiring extending in the first direction, and a resistance change film provided between the first wiring and the second wiring. Also, the semiconductor memory device includes a third wiring which is closer to the substrate than the second wiring and extends in a second direction intersecting with the first direction, a first semiconductor layer provided between the second wiring and the third wiring and connected to the second wiring and the third wiring, and a first electrode facing the first semiconductor layer. Also, the semiconductor memory device includes a fourth wiring which is farther from the substrate than the second wiring, is connected to the second wiring, and extends in a third direction intersecting with the first direction, a fifth wiring provided between the fourth wiring and the substrate, extending in the first direction, and connected to the fourth wiring, a sixth wiring provided between the fifth wiring and the substrate, a second semiconductor layer provided between the fifth wiring and the sixth wiring and connected to the fifth wiring and the sixth wiring, and a second electrode facing the second semiconductor layer.

According to another embodiment, a semiconductor memory device includes a substrate, a plurality of first wirings arranged in a first direction intersecting with a surface of the substrate and including a portion extending in a second direction intersecting with the first direction, a plurality of second wirings arranged in the second direction and extending in the first direction, a resistance change film provided between the portion of the first wiring extending in the second direction and the second wiring. Also, the semiconductor memory device includes a plurality of third wirings which are closer to the substrate than the plurality of second wirings and are arranged in the second direction, a plurality of first semiconductor layers provided between the plurality of second wirings and the plurality of third wirings, arranged in the second direction, and connected to the plurality of second wirings and the plurality of third wirings, and a first electrode extending in the second direction and facing the first semiconductor layer. Also, the semiconductor memory device includes a plurality of fourth wirings which are farther from the substrate than the plurality of second wirings and arranged in the second direction, a plurality of second semiconductor layers provided between the plurality of second wirings and the plurality of fourth wirings, arranged in the second direction, and connected to the plurality of second wirings and the plurality of fourth wirings, and a second electrode extending in the second direction and facing the second semiconductor layer. The semiconductor memory device further includes a control circuit connected to the plurality of first wirings, the plurality of third wirings, and the plurality of fourth wirings. In addition, the control circuit is configured to apply a first operating voltage to at least one of the plurality of third wirings and to apply a second operating voltage different from the first operating voltage to at least one other third wiring. The control circuit is configured to apply a third operating voltage to a fourth wiring of the plurality of fourth wirings corresponding to the third wiring to which the first operating voltage is applied, and to apply a fourth operating voltage different from the third operating voltage to a fourth wiring of the plurality of fourth wirings corresponding to the third wiring to which the second operating voltage is applied.

According to still another embodiment, a semiconductor memory device includes a substrate, a plurality of first wirings arranged in a first direction intersecting with a surface of the substrate, a plurality of second wirings arranged in a second direction intersecting with the first direction and extending in the first direction, and a resistance change film provided between the first wiring and the second wiring. Also, the semiconductor memory device further includes a third wiring which is closer to the substrate than the plurality of second wirings and extends in the second direction, a plurality of first semiconductor layers provided between the plurality of second wirings and the third wiring and connected to the plurality of second wirings and the third wiring, and a plurality of first electrodes arranged in the second direction and facing the plurality of first semiconductor layers. Also, the semiconductor memory device includes a plurality of second semiconductor layers electrically connected to the plurality of second wirings, one or a plurality of fourth wirings connected to the plurality of second semiconductor layers, and a plurality of second electrodes facing the plurality of second semiconductor layers. The semiconductor memory device further includes a control circuit connected to the plurality of first wirings, the third wiring, and the one or plurality of fourth wirings. The control circuit is configured such that, when a voltage to be transferred to one of the plurality of first wirings is set to a first write voltage, a voltage to be transferred to the plurality of other first wirings is set to a non-select voltage, a voltage to be transferred to one of the plurality of second wirings is set to a second write voltage, and the plurality of other second wirings are set in a floating state, if a non-select voltage when an absolute value of a difference between a voltage of the first wiring to which the first write voltage is transferred and a voltage of the second wiring to which the second write voltage is transferred becomes a maximum is set as a first voltage, the control circuit applies a voltage that coincides with or substantially coincides with the first write voltage to at least one of the plurality of first wirings and applies a voltage having a magnitude between the second write voltage and the first voltage to at least one of the plurality of first wirings.

Next, a semiconductor memory device according to embodiments will be described in detail with reference to the drawings. The following embodiments are merely examples and are not intended to limit the present disclosure.

In the present specification, a direction intersecting with a front surface of a substrate (e.g. a surface on which certain components described herein are disposed) is referred to as a first direction, a direction intersecting with the first direction is referred to as a second direction, a direction intersecting with the first direction and the second direction is referred to as a third direction. A predetermined direction parallel to the front surface of the substrate is referred to as an X-direction, a direction which is parallel to the front surface of the substrate and perpendicular to the X-direction is referred as a Y-direction, and a direction perpendicular to the front surface of the substrate is referred as a Z-direction. The Z-direction, the X-direction, and the Y-direction may correspond to one of the first direction, the second direction, and the third direction, respectively, or may not correspond to the first direction, second direction, and third direction, respectively.

In this specification, expressions such as “above” and “below” are defined by using the substrate as a reference. For example, a direction away from the substrate along the first direction is referred to as an upward direction, and a direction approaching the substrate along the first direction is referred to as a downward direction. Reference to a lower surface or a lower end in a certain configuration may be a reference to a surface or an end portion on the substrate side of this configuration. Reference to an upper surface or an upper end, may be a reference to a surface or an end portion on a side opposite to the substrate of this configuration. Further, a surface intersecting with the second direction or the third direction may be referred to as a side surface.

In this specification, a bipolar type configuration including a variable resistance element may be used as at least a portion of a memory cell. In such a case, the memory cell may be in a reset state (high resistance state) by application of a reset voltage having a first polarity, or may be in a set state (low resistance state) by application of a set voltage having a second polarity opposite to the first polarity. In the following, the former may be referred to as a “reset operation”, and the latter may be referred to as a “set operation”. The set operation and the reset operation may collectively be referred to as a “write operation”.

In this specification, a voltage applied to one electrode of a memory cell in a write operation may be referred to as a “first write voltage”, and a voltage applied to the other electrode may be referred to as a “second write voltage”. In the write operation, a voltage applied to a wiring to which the first and second write voltages are not applied may be referred to as a “non-select voltage”. In addition, the first write voltage, the second write voltage, and the non-select voltage may be collectively referred to as an “operating voltage”.

First Memory Cell Array

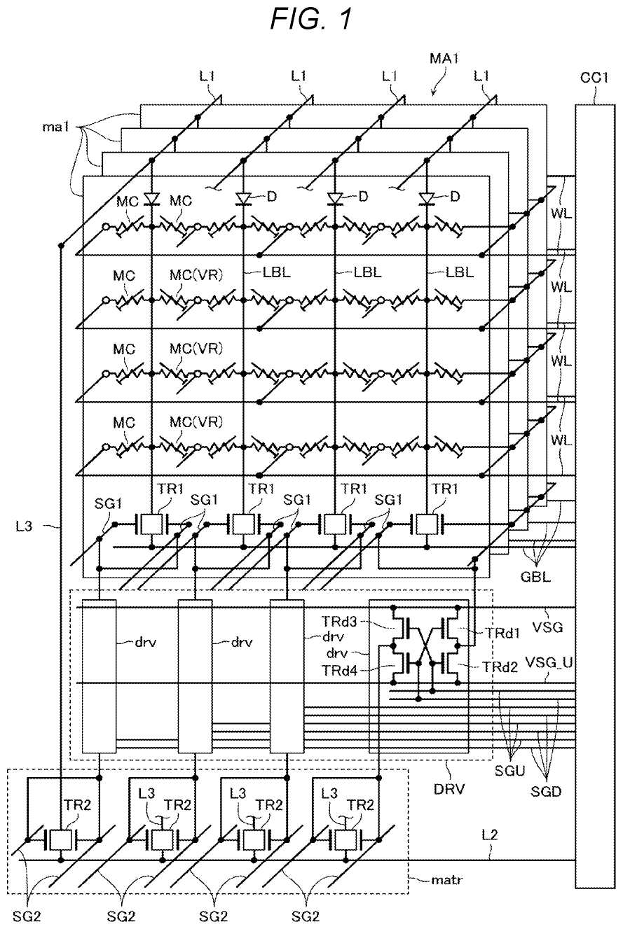

Next, a circuit configuration of a semiconductor memory device including a first memory cell array MA1 will be described with reference to FIG. 1. FIG. 1 is a schematic circuit diagram of a semiconductor memory device according to this embodiment. In FIG. 1, a portion of the configuration may be omitted from the drawing.

As illustrated in FIG. 1, the semiconductor storage device according to this embodiment includes the memory cell array MA1 for storing data and a control circuit CC1 for controlling the memory cell array MA1.

The memory cell array MA1 includes a plurality of circuit elements ma1 and a circuit element matr. The circuit element ma1 includes a plurality of word lines WL connected to the control circuit CC1, a plurality of local bit lines LBL, a plurality of memory cells MC connected to the plurality of word lines WL and the plurality of local bit lines LBL. The circuit element ma1 includes a global bit line GBL connected to the control circuit CC1, a plurality of select transistors TR1 connected to the global bit line GBL and the local bit line LBL, and select gate lines SG1 connected to the plurality of select transistors TR1. The circuit element ma1 includes diodes D connected to the plurality of local bit lines LBL. The other ends of the diodes D are connected to wirings L1.

Word lines WL are connected to all the circuit elements ma1, respectively.

The memory cell MC is a memory element that stores data of 1 bit or more. The memory cell MC is a bipolar type memory cell including a pair of electrodes and a variable resistance element VR provided between these electrodes.

The select transistor TR1 is a field-effect transistor. A drain electrode of the select transistor TR1 is connected to the global bit line GBL, and a source electrode thereof is connected to the local bit line LBL. A gate electrode thereof is a part of the select gate line SG1.

The select gate lines SG1 are connected to all the circuit elements ma1, respectively.

The diode D is, for example, a diode having a p-n junction or the like. In the diode D, a direction in which current flows from the wiring L1 to the local bit line LBL is defined as a forward direction.

The wiring L1 is commonly connected to a local bit line LBL of each of the circuit elements ma1 via the diode D.

The circuit element matr includes a plurality of wirings L3 connected to the wiring L1, a wiring L2 connected to the control circuit CC1, a plurality of select transistors TR2 connected to the wiring L2 and the wirings L3, and select gate lines SG2 connected to gate electrodes of the select transistors TR2.

The select transistor TR2 is a field-effect transistor. A drain electrode of the select transistor TR2 is connected to the wiring L2, a source electrode thereof is connected to the wiring L3, and a gate electrode thereof is connected to the select gate line SG2.

The select gate lines SG2 are connected to a driver circuit DRV of the control circuit CC1.

The control circuit CC1 includes, for example, a voltage generation circuit for generating an operating voltage having a desired magnitude, a decode circuit for generating a desired operating voltage for a desired wiring according to an input address, a sense amplifier circuit for detecting a current or a voltage flowing in the global bit line GBL, and the like. Further, the control circuit CC1 includes the driver circuit DRV.

The driver circuit DRV includes a plurality of circuit elements dry provided corresponding to the select transistors TR1 and TR2. Each circuit element dry turns ON one of the select transistors TR1 and TR2 and turns OFF the other of the select transistors TR1 and TR2. That is, the circuit element dry connects the corresponding local bit line LBL to one of the global bit line GBL and the wiring L2.

The circuit elements dry are connected to an ON voltage supply line VSG and an OFF voltage supply line VSG_U which supply an ON voltage and an OFF voltage to be supplied to the gate electrodes of the select transistors TR1 and TR2. The circuit elements dry are connected to signal lines SGD for supplying a signal for connecting the local bit lines LBL to the global bit lines GBL and signal lines SGU for supplying a signal for connecting the local bit lines LBL to the wiring L2, respectively. When one of the signal lines SGD and SGU is in an H state, the other is in an L state.

Transistors TRd1 are connected to the select gate lines SG1 and an ON voltage supply line VSG. Transistors TRd2 are connected to the select gate lines SG1 and the OFF voltage supply line VSG_U. Transistor TRd3 are connected to the select gate lines SG2 and the ON voltage supply line VSG. Transistors TRd4 are connected to the select gate lines SG2 and the OFF voltage supply line VSG_U. The signal lines SGD are connected to the gate electrodes of the transistor TRd1 and the transistor TRd4. The signal lines SGU are connected to the gate electrodes of the transistors TRd2 and the transistors TRd3.

The configuration of the circuit element dry may be appropriately changed. For example, although four NMOS transistors are used in the illustrated example, four PMOS transistors may be used, or NMOS transistors and PMOS transistors may be combined. Another number of transistors may be implemented.

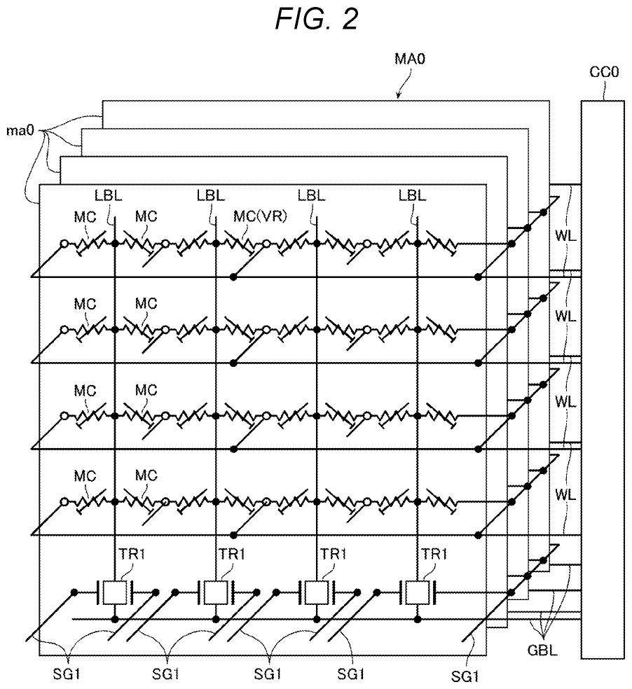

Here, according to the semiconductor memory device having such a configuration, stable operation can be realized. In the following, in order to explain this point, a semiconductor memory device according to a comparative example will be described with reference to FIG. 2.

As illustrated in FIG. 2, the semiconductor memory device according to the comparative example includes a memory cell array MA0 for storing data and a control circuit CC0 for controlling the memory cell array MA0. The memory cell array MA0 is configured in a similar manner as the memory cell array MA1, but does not include the circuit element matr (FIG. 1) and the like.

For example, when a read operation or a write operation is performed in such a semiconductor memory device, the select transistor TR1 connected to the selected memory cells MC may be turned ON and the other select transistors TR1 may be turned OFF. In this case, although the selected local bit line LBL connected to the selected memory cell MC is connected to the global bit line GBL, all the other non-selected local bit lines LBL are in a floating state. As a result, it can be challenging to control a leakage current in the memory cell array MA0, an SN ratio in the read operation or the like may deteriorate, and the voltage applied to the selected memory cell MC decreases in some cases.

Here, as described with reference to FIG. 1, the semiconductor memory device according to this embodiment includes the select transistor TR2 connected to the local bit lines LBL and the wiring L2, in addition to the select transistors TR1 connected to the local bit lines LBL and the global bit lines GBL. Accordingly, when the selected local bit line LBL is connected to the global bit line GBL, it is possible to connect a plurality of non-selected local bit lines LBL to the line L2 and to control the voltages of the non-selected local bit lines. Accordingly, a voltage of a non-selected local bit line LBL and a voltage of a non-selected word line WL can be independently controlled, the magnitude of the leak current can be suitably controlled, and a stable operation can be realized.

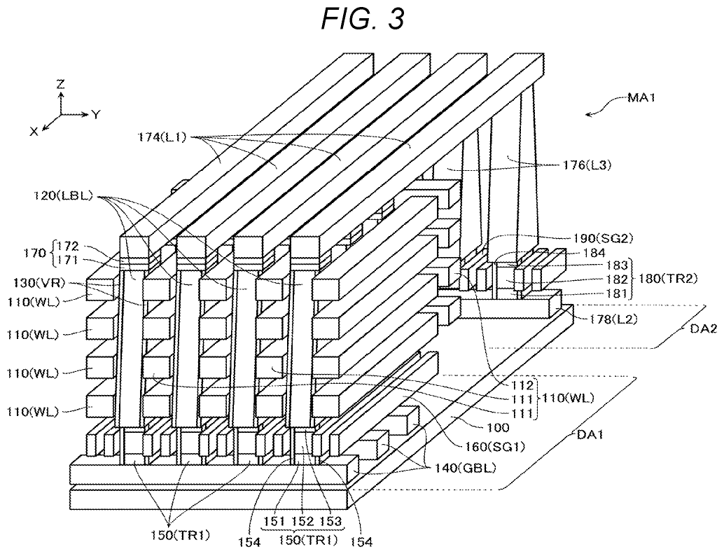

The configuration illustrated in FIG. 1 can be implemented in various manners. FIG. 3 is a schematic perspective view illustrating an example embodiment. In FIG. 3, a portion of the configuration may be omitted from the drawing.

FIG. 3 illustrates a substrate 100 and the memory cell array MA1 provided above the substrate 100.

The substrate 100 is, for example, a semiconductor substrate such as single crystal silicon (Si). On the upper surface of the substrate 100, transistors, wirings, and the like constituting a portion or the whole of the control circuit CC1 are provided.

The memory cell array MA1 includes a plurality of wirings 110 arranged in the Z-direction, a plurality of wirings 120 extending in the Z-direction, a plurality of resistance change films 130 provided between the plurality of wirings 110 and the plurality of wirings 120. The memory cell array MA1 includes a plurality of wirings 140 provided under configurations of these constituent elements, a plurality of semiconductor layers 150 connected to lower ends of the wirings 120 and the wirings 140, a plurality of wirings 160 facing the semiconductor layers 150. The memory cell array MA1 further includes a plurality of semiconductor layers 170 connected to the upper ends of the wirings 120, a plurality of wirings 174 connected to the semiconductor layers 170 and extending in the X-direction, a plurality of wirings 176 connected to the wirings 174 and extending in the Z-direction, a wiring 178 provided below the wirings 176 and extending in the Y-direction, a plurality of semiconductor layers 180 connected to the lower ends of the wirings 176 and the wiring 178, and wirings 190 facing the semiconductor layers 180.

The wirings 110 may be a plurality of straight hexagonal prism shaped wirings (although other shapes can be implemented) arranged in the Z-direction. Each wiring 110 functions as each word line WL (FIG. 1) and one electrode of each of the plurality of memory cells MC (FIG. 1) arranged in the X-direction or arranged in the Y-direction, respectively. The wirings 110 include a plurality of first portions 111 and a second portion 112 connected to the plurality of first portions 111. The plurality of first portions 111 are arranged in the Y-direction and extend in the X-direction. The second portion 112 extends in the Y-direction and is commonly connected to one end of each of the plurality of first portions 111 in the X-direction.

A plurality of wirings 120 are arranged in the X-direction and the Y-direction and extend in the Z-direction. Each wiring 120 functions as a local bit line LBL (FIG. 1), an other electrode of the plurality of memory cells MC (FIG. 1) arranged in the Z-direction, and a source electrode of the select transistor TR1 (FIG. 1).

The resistance change films 130 are provided on both side surfaces of the wiring 120 in the Y-direction, and a plurality of resistance change films 130 are arranged corresponding to the wiring 120 in the X-direction and the Y-direction. Further, the resistance change films 130 extend in the Z-direction along the side surfaces of the wirings 120 in the Y-direction and function as a plurality of variable resistance elements VR (FIG. 1) arranged in the Z-direction.

Each resistance change film 130 may include a stacked film of a metal layer of copper (Cu), silver (Ag) or the like, and an insulating layer such as silicon oxide (SiO₂), for example. Each resistance change film 130 may be a transition metal oxide such as hafnium oxide (HfOₓ), for example. Each resistance change film 130 may be one in which a resistance value reversibly changes by a change in a crystal structure, or the like.

The resistance change films 130 may be provided, for example, on both side surfaces of the first portions 111 of the wirings 110 in the Y-direction and the plurality of resistance change films 130 may be arranged corresponding to the first portions 111 in the Y-direction and the Z-direction. In this case, the resistance change films 130 may function as the plurality of variable resistance elements VR extending in the X-direction along the side surface of the first portion 111 in the Y-direction and arranged in the X-direction. The resistance change films 130 may function, for example, as the plurality of variable resistance elements VR extending in the X-direction and the Z-direction and arranged in the Z-direction and the X-direction.

The plurality of wirings 140 are arranged corresponding to the wirings 120 in the X-direction and extend in the Y-direction. The wirings 140 function as drain electrodes of the global bit lines GBL (FIG. 1) and the plurality of select transistors TR1 (FIG. 1) arranged in the Y-direction, respectively.

A plurality of semiconductor layers 150 are arranged corresponding to the wirings 120 in the X-direction and the Y-direction. Each semiconductor layer 150 is, for example, a semiconductor layer of an oxide semiconductor such as polycrystalline silicon (p-Si) or a metal oxide. Each semiconductor layer 150 includes a first region 151, a second region 152 provided above the first region, and a third region 153 provided above the second region. The first region 151 contains n-type impurities such as phosphorus (P) and functions as a drain region of each select transistor TR1 (FIG. 1). The second region 152 contains p-type impurities such as boron (B) and functions as a channel region of each select transistor TR1 (FIG. 1). The third region 153 contains n-type impurities such as phosphorus (P) and functions as a source region of each select transistor TR1 (FIG. 1).

Insulating layers 154 including SiO₂ or the like are provided between the semiconductor layers 150 and the wirings 160. The insulating layers 154 function as gate insulating films of the select transistors TR1 (FIG. 1).

The wirings 160 are provided on both side surfaces of the semiconductor layers 150 in the Y-direction, and the plurality of wirings 160 are arranged corresponding to the semiconductor layer 150 in the Y-direction. The wirings 160 extend in the X-direction and face the side surfaces of the second region 152 of the plurality of semiconductor layers 150, which are arranged in the X-direction, in the Y-direction. The wirings 160 function as the select gate lines SG1 (FIG. 1) and gate electrodes of the plurality of select transistors TR1 (FIG. 1) arranged in the X-direction, respectively.

A plurality of semiconductor layers 170 are arranged corresponding to the wirings 120 in the X-direction and the Y-direction. Each semiconductor layer 170 functions as a diode D (FIG. 1). Each semiconductor layer 170 is a semiconductor layer including, for example, an oxide semiconductor such as polycrystalline silicon (p-Si) or a metal oxide. Each semiconductor layer 170 includes a first region 171 and a second region 172 provided above the first region. The first region 171 contains an n-type impurity such as phosphorus (P), for example. The second region 172 contains a p-type impurity such as boron (B), for example.

A plurality of wirings 174 are arranged corresponding to the wirings 120 in the Y-direction and extend in the X-direction. Each wiring 174 functions as the wiring L1 (FIG. 1).

The wirings 176 are provided between the wirings 174 and the substrate 100. Each wiring 176 functions as each wiring L3 (FIG. 1) and as a source electrode of each select transistor TR2 (FIG. 1). The plurality of wirings 176 are arranged corresponding to the wirings 174 in the Y-direction and extend in the Z-direction.

The wiring 178 is provided between the wirings 176 and the substrate 100. The wiring 178 functions as the wiring L2 (FIG. 1), and functions as the drain electrode of each of the plurality of select transistors TR2 (FIG. 1) arranged in the Y-direction.

A plurality of semiconductor layers 180 are arranged corresponding to the wirings 176 in the Y-direction. Each semiconductor layer 180 is, for example, a semiconductor layer of an oxide semiconductor such as polycrystalline silicon (p-Si) or a metal oxide. Each semiconductor layer 180 includes a first region 181, a second region 182 provided above the first region, and a third region 183 provided above the second region. The first region 181 contains an n-type impurity such as phosphorus (P) and functions as a drain region of each select transistor TR2 (FIG. 1). The second region 182 contains a p-type impurity such as boron (B) and functions as a channel region of each select transistor TR2 (FIG. 1). The third region 183 contains n-type impurities such as phosphorus (P) and functions as a source region of each select transistor TR2 (FIG. 1).

Insulating layers 184 of SiO₂ or the like are provided between the semiconductor layers 180 and the wirings 190. Each insulating layer 184 functions as a gate insulating film of each select transistor TR2 (FIG. 1).

The wirings 190 are provided on both side surfaces of the semiconductor layers 180 in the Y-direction, and a plurality of wirings 190 are arranged corresponding to the semiconductor layers 180 in the Y-direction. Each wiring 190 faces the side surface of the second region 182 of each semiconductor layer 180 in the Y-direction. The wirings 190 function as the select gate lines SG2 and function as the gate electrodes of the select transistors TR2 (FIG. 1), respectively.

The wirings 110, the wirings 120, the wirings 140, the wirings 160, the wirings 174, the wirings 176, the wiring 178, and the wirings 190 are formed by, or include, stacking films of titanium nitride (TiN) and tungsten (W), polysilicon (p-Si) implanted with impurities, or other conductive layers. Further, insulating layers (not illustrated) including, for example, SiO₂, may be provided between these wirings.

In the illustrated example, two wirings 160 are provided between two semiconductor layers 150 adjacent in the Y-direction. However, one wiring 160 may be provided between the semiconductor layers 150 adjacent in the Y-direction. The wirings 160 may have a so-called surround gate type structure that surrounds the outer peripheral surface of the second region 152 of each semiconductor layer 150 in an XY cross section. The same applies to the relationship between the semiconductor layers 180 and the wirings 190.

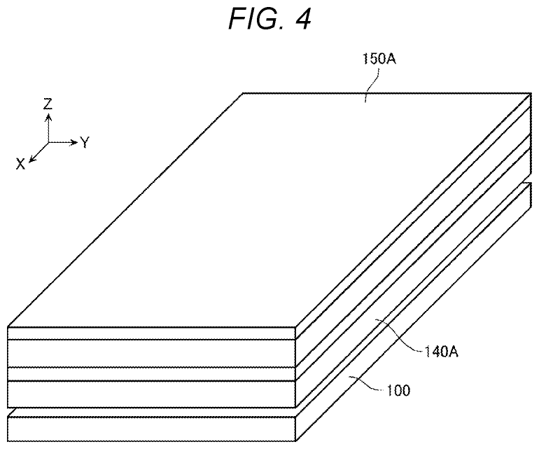

Next, a manufacturing method of the configuration illustrated in FIG. 3 will be described with reference to FIG. 4 to FIG. 14. In FIG. 4 to FIG. 14, a portion of the configuration may be omitted from the drawings.

In this manufacturing method, for example, transistors, wirings, and the like constituting a portion or the whole of the control circuit CC1 are formed or disposed on the upper surface of the substrate 100.

Next, as illustrated in FIG. 4, a conductive layer 140A corresponding to the wirings 140 and 178 and a semiconductor layer 150A corresponding to the semiconductor layers 150 and 180 are formed above the substrate 100. For example, the conductive layer 140A and an amorphous silicon layer are formed by a method such as a chemical vapor deposition (CVD) or the like. The semiconductor layer 150A is formed by using this amorphous silicon layer as a polysilicon layer by a method such as a rapid thermal anneal (RTA) or the like.

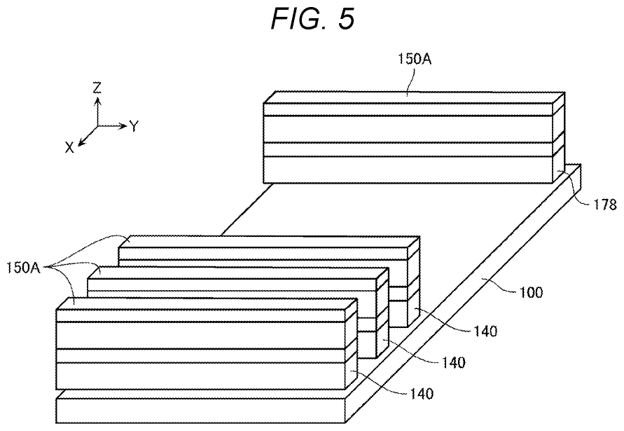

Next, as illustrated in FIG. 5, the conductive layer 140A and the semiconductor layer 150A are divided in the X-direction. This process is performed by a method such as reactive ion etching (RIE), for example. In this process, the wirings 140 and 178 are formed.

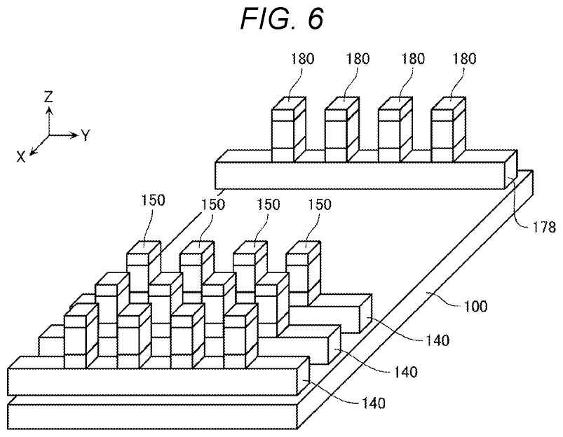

Next, as illustrated in FIG. 6, the semiconductor layer 150A is divided in the Y-direction. This process is performed by, for example, a method such as the RIE. In this process, the semiconductor layers 150 and 180 are formed.

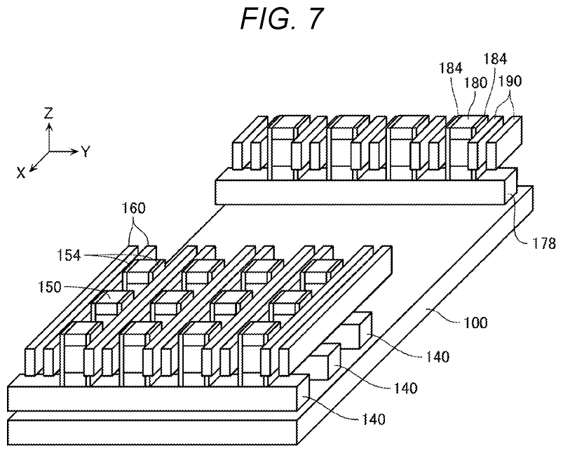

Next, as illustrated in FIG. 7, insulating layers 154 and 184 and wirings 160 and 190 are formed. For example, the insulating layers 154 and 184 and the conductive layers corresponding to the wirings 160 and 190 are formed on the side surfaces of the semiconductor layers 150 and 180 in the Y-direction by a method such as the CVD. The conductive layers are divided in the Y-direction by the RIE or the like to form the wirings 160 and 190.

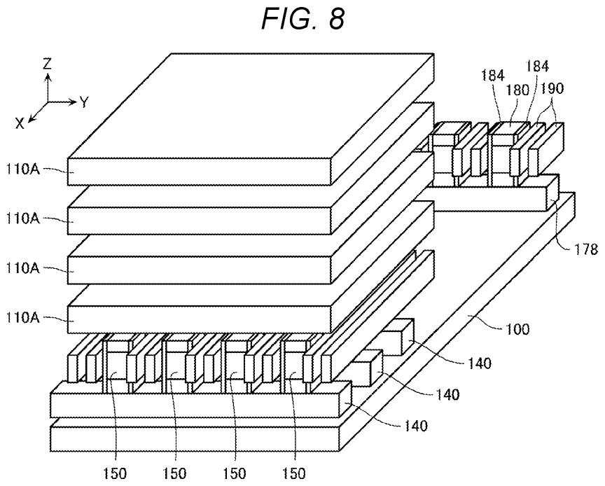

Next, as illustrated in FIG. 8, a plurality of word line layers 110A are formed above the configuration illustrated in FIG. 7. This process is performed by, for example, a method such as the CVD. The word line layer 110A may be a sacrifice layer of SiN or the like, or may be an amorphous silicon layer or a polycrystalline silicon layer into which impurities are implanted.

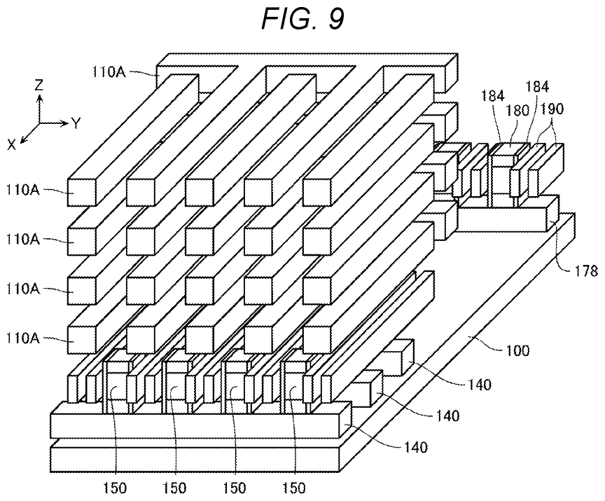

Next, as illustrated in FIG. 9, the plurality of word line layers 110A are processed into a straight hexagonal prism shape (or another appropriate shape) to expose the upper surface of the semiconductor layer 150. This process is performed by, for example, a method such as the RIE.

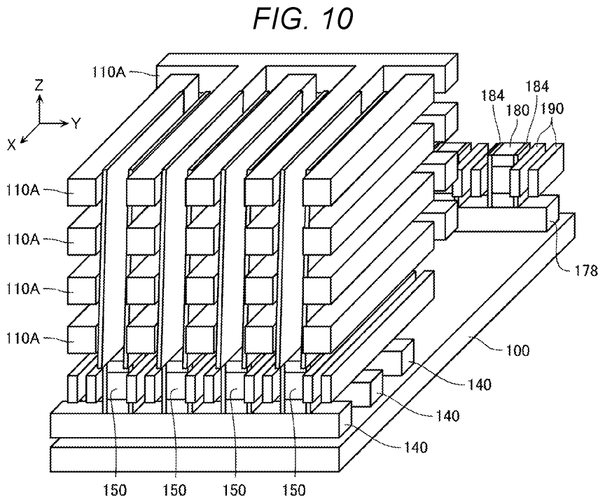

Next, as illustrated in FIG. 10, the resistance change films 130 are formed on the side surfaces of the plurality of word line layers 110A in the Y-direction. This process is performed by, for example, a method such as the CVD. A portion of each resistance change film 130 formed on the upper surface of the semiconductor layer 150 is removed by a method such as the RIE or the like.

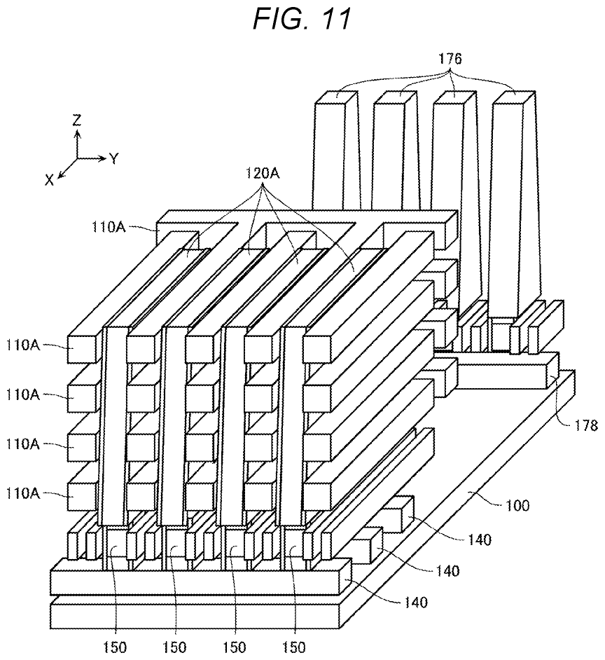

Next, as illustrated in FIG. 11, a conductive layer 120A and the wiring 176 corresponding to the wiring 120 are formed. This process is performed by, for example, a method such as the CVD.

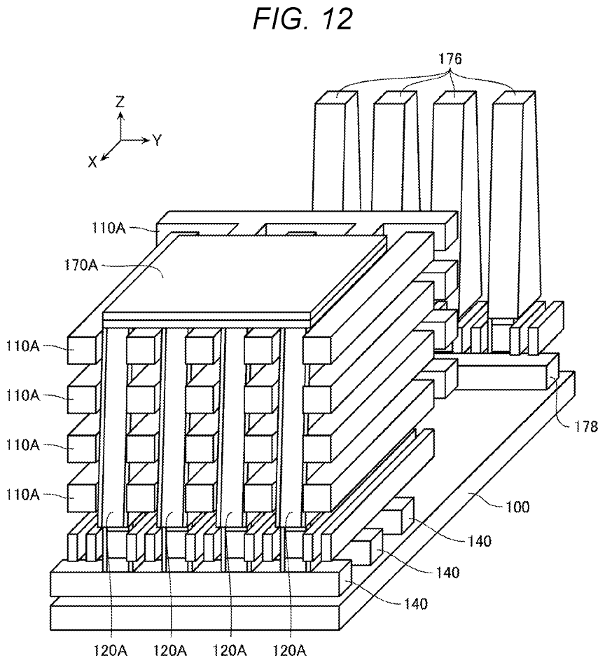

Next, as illustrated in FIG. 12, a semiconductor layer 170A corresponding to the semiconductor layer 170 is formed on the upper surface of the conductive layer 120A. This process is performed by, for example, a method such as the CVD.

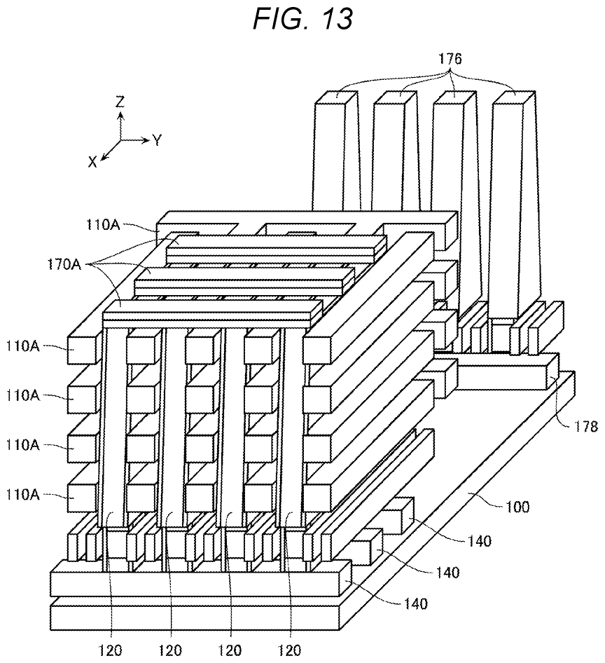

Next, as illustrated in FIG. 13, the conductive layer 120A and the semiconductor layer 170A are divided in the X-direction. This process is performed by, for example, a method such as the RIE. In this process, the wiring 120 is formed.

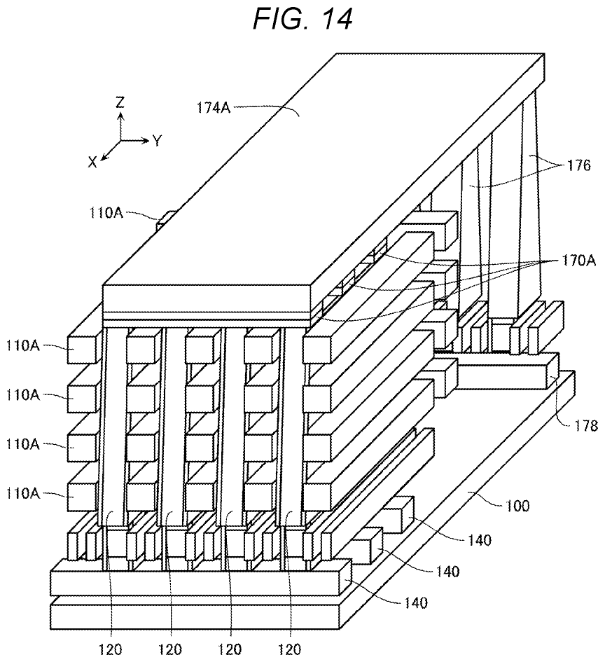

Next, as illustrated in FIG. 14, a conductive layer 174A corresponding to the wiring 174 is formed on the upper surface of the semiconductor layer 170A and the wiring 176. This process is performed by, for example, a method such as the CVD.

Next, the configuration illustrated in FIG. 3 is formed by dividing the conductive layer 174A and the semiconductor layer 170A in the Y-direction by a method such as the RIE or the like.

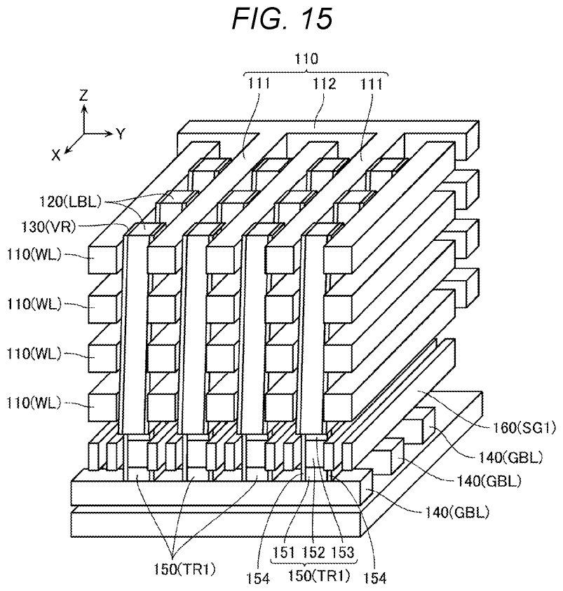

As described with reference to FIGS. 4 to 7, when forming the configuration illustrated in FIG. 3, respective configurations (150, 154, and 160) of the select transistors TR1 and respective configurations (180, 184, and 190) of the select transistors TR2 are collectively formed. Furthermore, as described with reference to FIG. 11, the wirings 120 and 176 are also formed collectively. Accordingly, the number of manufacturing processes does not increase substantially as compared with the configuration without the select transistor TR2 or the like as illustrated in FIG. 15, for example.

According to such a method, it is possible to terminate a thermal process when forming the semiconductor layers 150 and 180 at once. Accordingly, it is possible to prevent deterioration of the characteristics of transistors and the like on the upper surface of the substrate 100 as the number of thermal processes increases.

According to such a method, it is possible to perform the thermal process in forming the semiconductor layers 150 and 180 before the resistance change film 130 is formed. Accordingly, deterioration of the characteristics of the resistance change film 130 caused by the thermal process can be prevented.

Second Memory Cell Array

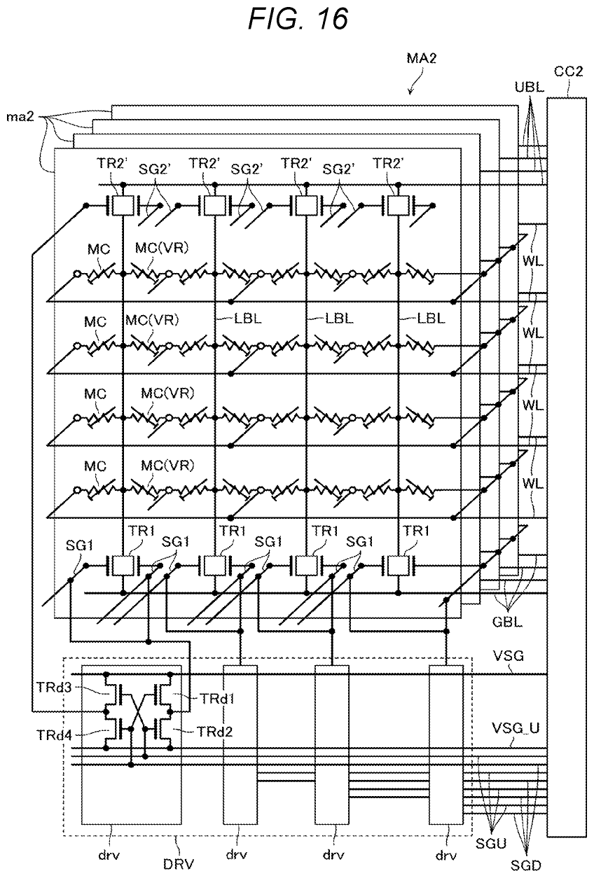

Next, a circuit configuration of a semiconductor memory device including a second memory cell array MA2 will be described with reference to FIG. 16. FIG. 16 is a schematic circuit diagram of the semiconductor memory device according to this embodiment. In FIG. 16, a portion of the configuration may be omitted from the drawing. In the following description, same reference numerals may be used to refer to same or similar components as are included in the memory cell array MA1, and the description thereof may be omitted.

As illustrated in FIG. 16, the semiconductor memory device according to this embodiment includes a memory cell array MA2 for storing data and a control circuit CC2 for controlling the memory cell array MA2.

The memory cell array MA2 includes a plurality of circuit elements ma2. The circuit element ma2 is configured similarly to the circuit element ma1 (FIG. 1), but omits the diode D. The circuit element ma2 includes an upper layer bit line UBL connected to a control circuit CC2, a plurality of select transistors TR2′ connected to an upper layer bit line UBL and local bit lines LBL, and select gate lines SG2′ connected to gate electrodes of the plurality of select transistors TR2′.

The select transistor TR2′ is a field-effect transistor. A drain electrode of the select transistor TR2′ is connected to the upper layer bit line UBL, the source electrode thereof is connected to the local bit line LBL, and the gate electrode thereof is connected to the select gate line SG2′.

Each select gate line SG2′ is commonly connected to the gate electrode of one select transistor TR2′ of each of all the circuit elements ma2.

The control circuit CC2 is configured in a similar manner as the control circuit CC1 (FIG. 1). However, the circuit element dry of the driver circuit DRV turns one of the select transistors TR1 and TR2′ ON and turns the other OFF.

According to such a configuration, similar to the memory cell array MA1, the voltage of the non-selected local bit line LBL and the voltage of the non-selected word line WL can be independently controlled, the magnitude of the leak current can be suitably controlled, and a stable operation can be realized.

Further, in this embodiment, in the write operation or the like, a voltage to be applied to the upper bit line UBL corresponding to the selected global bit line GBL and a voltage to be applied to the upper layer bit line UBL corresponding to the non-selected global bit line GBL may be selectively set (e.g., to different magnitudes). For example, when the operating voltage applied to the selected global bit line GBL is larger than the operating voltage applied to the non-selected global bit line GBL, an operation voltage larger than that of the upper layer bit line UBL corresponding to the latter may be applied to the upper layer bit line UBL corresponding to the former. The same applies to voltages of an opposite relationship.

According to such a method, the voltage applied to the select transistors TR1 and TR2′ becomes smaller, for example, as compared with the case where the same voltage is applied to all the upper layer bit lines UBL. With this configuration, it is possible to extend the life of the select transistors TR1 and TR2′.

The control circuit CC2 has a configuration in which such a method is realized. The control circuit CC2 includes first to fourth voltage supply lines for supplying first to fourth operating voltages, a plurality of first voltage transfer transistors capable of connecting the first and second voltage supply lines to the plurality of selected global bit lines GBL, and a plurality of second voltage transfer transistors capable of connecting the third and fourth voltage supply lines to the plurality of upper layer bit lines UBL. Signal lines for transferring a common signal may be connected to the gate electrodes of the corresponding first voltage transfer transistor and second voltage transfer transistor, respectively. The second voltage supply line may supply the same voltage as the third voltage supply line or the fourth voltage supply line, and may be connected to the third voltage supply line or the fourth voltage supply line.

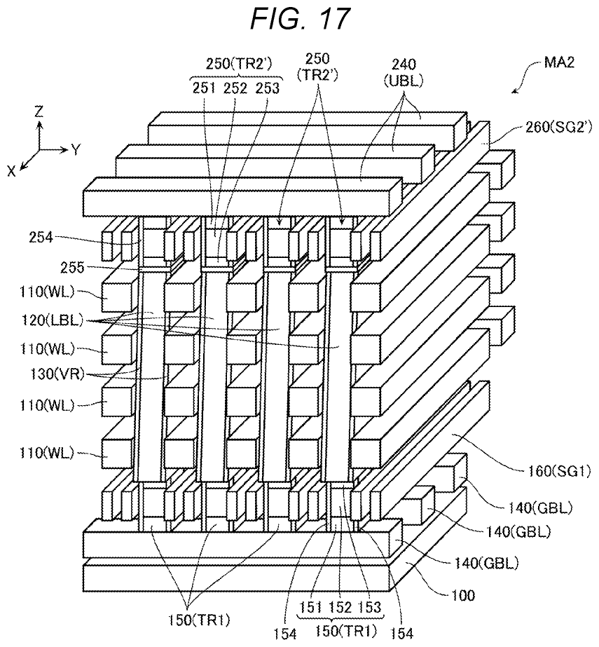

The configuration illustrated in FIG. 16 can be implemented in various manners. FIG. 17 is a schematic perspective view illustrating an example of an embodiment. In FIG. 17, a portion of the configuration may be omitted from the drawing. In the following description, same reference numerals may be used to refer to same or similar components as shown in FIG. 3 and the like, and the description thereof may be omitted.

FIG. 17 illustrates the substrate 100 and the memory cell array MA2 provided above the substrate 100.

The memory cell array MA2 is configured in a similar manner as the memory cell array MA1 (FIG. 3), but the memory cell array MA2 omits the semiconductor layer 170, the wiring 174, the wiring 176, the wiring 178, the semiconductor layer 180, and the wiring 190. The memory cell array MA2 includes a plurality of wirings 240 provided above the plurality of wirings 110 and the like, semiconductor layers 250 connected to upper ends of wirings 120, wirings 240, and wirings 260 facing the semiconductor layers 250.

A plurality of wirings 240 are arranged in the X-direction corresponding to the wirings 120 and extend in the Y-direction. The wirings 240 function as the upper layer bit lines UBL (FIG. 16) and drain electrodes of the plurality of select transistors TR2′ (FIG. 16) arranged in the Y-direction, respectively.

A plurality of semiconductor layers 250 are arranged corresponding to the wirings 120 in the X-direction and the Y-direction. The semiconductor layer 250 is, for example, a semiconductor layer including an oxide semiconductor such as polycrystalline silicon (p-Si) or a metal oxide. The semiconductor layer 250 includes a first region 251, a second region 252 provided below the first region, and a third region 253 provided below the second region. The first region 251 contains n-type impurities such as phosphorus (P) and functions as a drain region of the select transistor TR2′ (FIG. 16). The second region 252 contains p-type impurities such as boron (B) and functions as a channel region of the select transistor TR2′ (FIG. 16). The third region 253 contains n-type impurities such as phosphorus (P) and functions as a source region of the select transistor TR2′ (FIG. 16).

Insulating layers 254 of SiO₂ or the like are provided between the semiconductor layers 250 and the wirings 260. Each insulating layer 254 functions as a gate insulating film of each select transistor TR1 (FIG. 16). Further, conductive layers 255 of TiN or the like are provided between the semiconductor layers 250 and the wirings 120. Each conductive layer 255 includes a material having a melting point lower than a crystallization temperature of the semiconductor layer 250.

The wirings 260 are provided on both side surfaces of the semiconductor layers 250 in the Y-direction, and a plurality of wirings 260 are arranged corresponding to the semiconductor layers 250 in the Y-direction. The wirings 260 extend in the X-direction and face the side surfaces of the second regions 252 of the plurality of semiconductor layers 250 arranged in the X-direction in the Y-direction. The wirings 260 function as the select gate lines SG2′ (FIG. 16) and gate electrodes of the plurality of select transistors TR2′ (FIG. 16) arranged in the X-direction, respectively.

The wiring 240 and the wiring 260 include, for example, stacked films of one or more of titanium nitride (TiN), tungsten (W), polycrystalline silicon (p-Si), or other conductive layers into which impurities are implanted. Insulating layers (not illustrated) of SiO₂ or the like may be provided between these wirings.

In the illustrated example, two wirings 260 are provided between two semiconductor layers 250 adjacent in the Y-direction. However, one wiring 260 may be provided between the semiconductor layers 250 adjacent in the Y-direction. Further, the wiring 260 may have a so-called surround gate type structure that surrounds the outer peripheral surface of the second region 252 of the semiconductor layer 250 in the XY cross section.

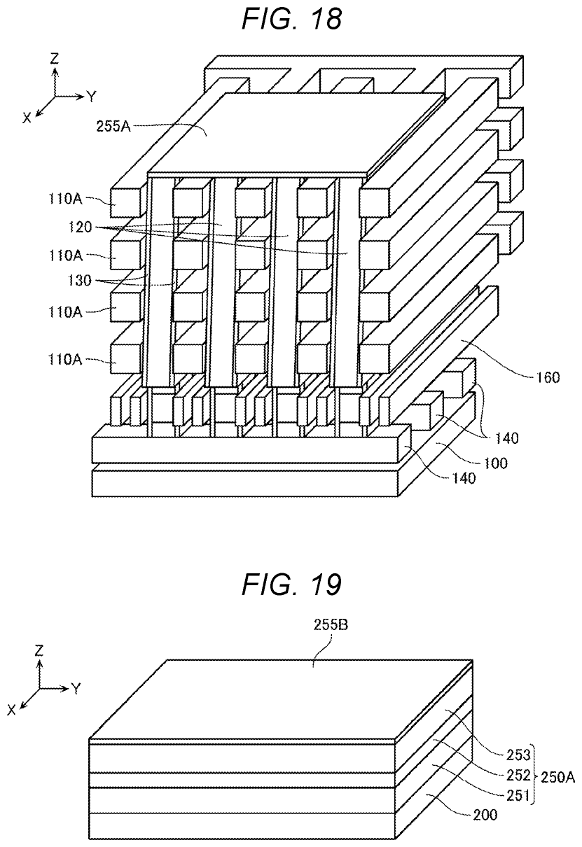

Next, a manufacturing method with the configuration illustrated in FIG. 17 will be described with reference to FIG. 18 to FIG. 25. In FIG. 18 to FIG. 25, a portion of the configuration may be omitted from the drawings.

In this manufacturing method, for example, transistors, wirings, and the like constituting a portion or the whole of the control circuit CC2 are formed on the upper surface of the substrate 100.

Next, the processes described with reference to FIGS. 4 to 11 and the processes described with reference to FIG. 13 are performed.

Next, as illustrated in FIG. 18, a conductive layer 255A corresponding to the conductive layer 255 is formed on the upper surfaces of the wirings 120. This process is performed by, for example, a method such as the CVD.

Next, as illustrated in FIG. 19, a semiconductor layer 250A corresponding to the semiconductor layer 250 and a conductive layer 255B corresponding to the conductive layer 255 are formed on a substrate 200 different from the substrate 100. For example, an amorphous silicon layer is formed by a method such as the CVD and the amorphous silicon layer is used as a polysilicon layer by a method such as the RTA, thereby forming the semiconductor layer 250A. The conductive layer 255B is formed on the upper surface of the semiconductor layer 250A by a method such as the CVD.

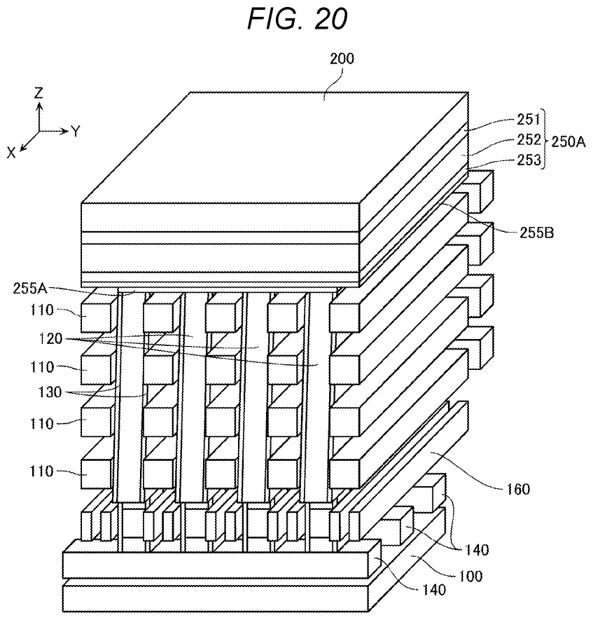

Next, as illustrated in FIG. 20, the upper surface of the substrate 100 is placed to face the upper surface of the substrate 200, and the conductive layer 255A and the conductive layer 255B are brought into contact with each other.

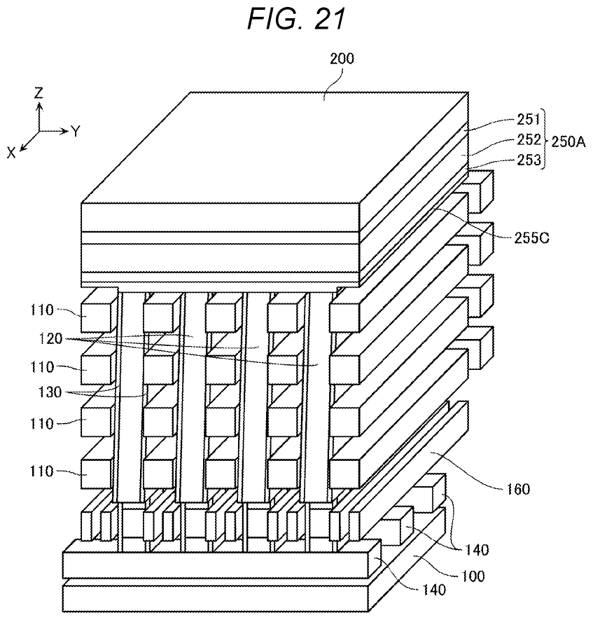

Next, as illustrated in FIG. 21, the conductive layer 255A and the conductive layer 255B are integrated to form a conductive layer 255C. This process is performed by a method such as heat treatment.

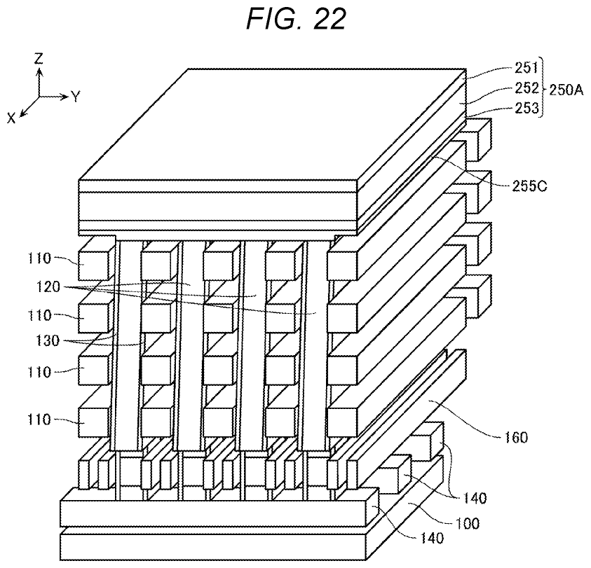

Next, as illustrated in FIG. 22, the substrate 200 is removed. This process is performed by a method such as etch-back by the RIE, for example.

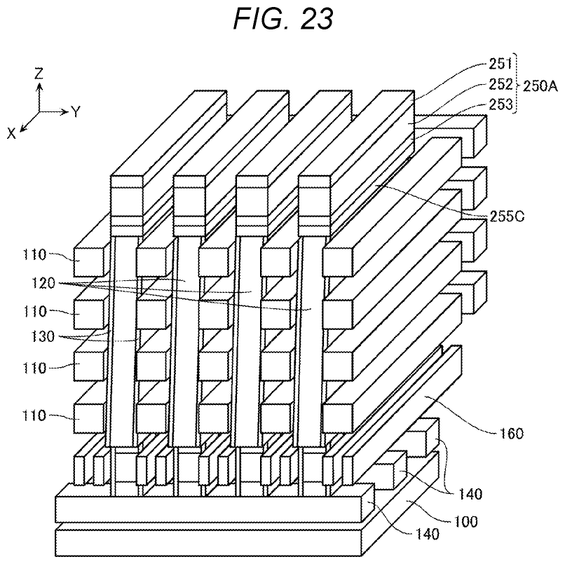

Next, as illustrated in FIG. 23, the semiconductor layer 250A is divided in the Y-direction. This process is performed by, for example, a method such as the RIE.

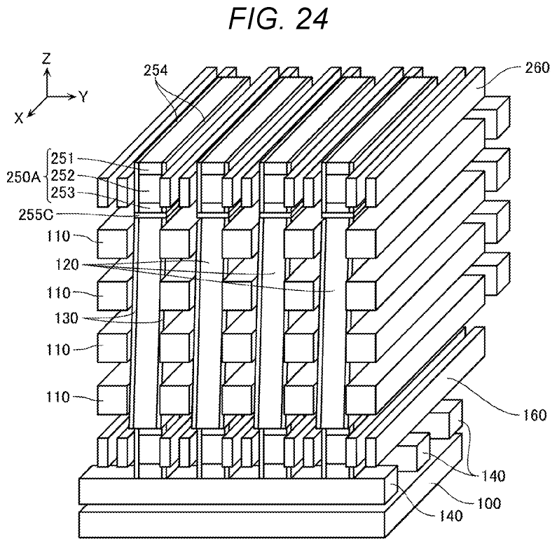

Insulating layers 254 and wirings 260 are formed as illustrated in FIG. 24. For example, the insulating layers 254 and the conductive layer corresponding to the wirings 260 are formed on the side surfaces of the semiconductor layers 250A in the Y-direction by a method such as the CVD. The conductive layer is divided in the Y-direction by a method such as RIE or the like to form the wirings 260.

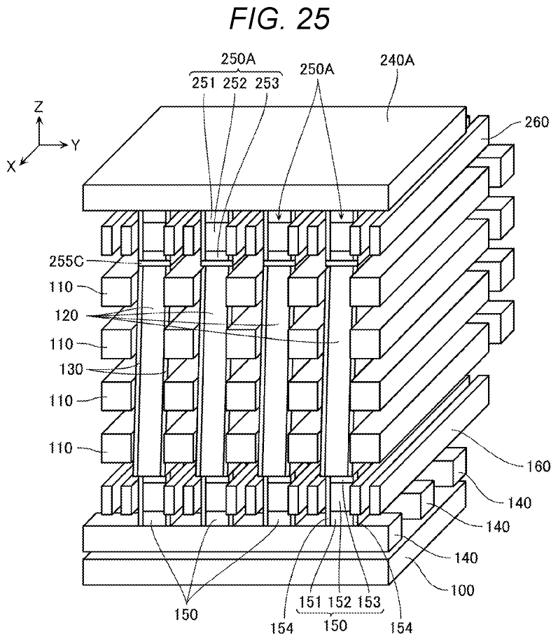

Next, as illustrated in FIG. 25, a conductive layer 240A corresponding to the wirings 240 is formed on the upper surfaces of the semiconductor layers 250A. This process is performed by, for example, a method such as the CVD.

Next, the semiconductor layers 250A and the conductive layer 240A are divided in the X-direction by a method such as the RIE or the like to form the structure illustrated in FIG. 17.

As described above, when forming the configuration illustrated in FIG. 17, the thermal process for forming the semiconductor layers 250 is performed on the substrate 200 (and, for example, is not performed on the substrate 100). Accordingly, it is possible to prevent deterioration of the characteristics of transistors and the like on the upper surface of the substrate 100 as the number of thermal processes increases. In addition, degradation of the characteristics of the resistance change film 130 caused by the thermal process can be prevented.

Layout

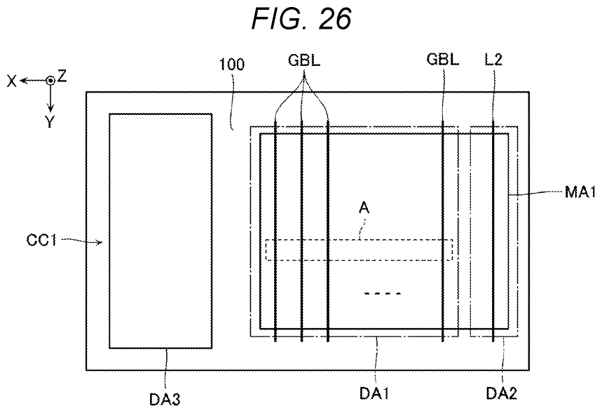

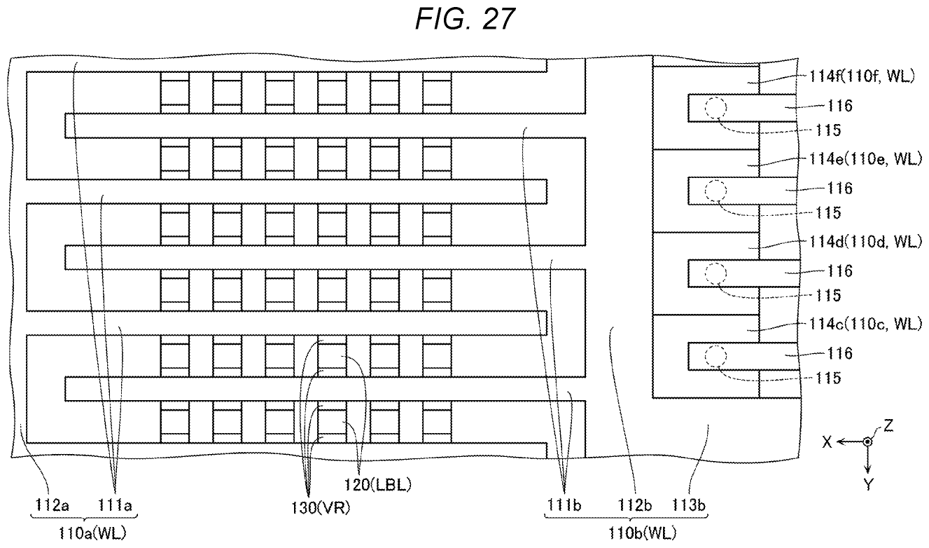

Next, a layout on the substrate 100 will be described with reference to FIGS. 26 and 27.

The layout on the substrate 100 can be implemented in various manners. FIG. 26 is a schematic plan view illustrating the layout on the substrate 100 having the configuration illustrated in FIG. 3. In FIG. 26, a portion of the configuration may be omitted from the drawing.

As illustrated in FIG. 26, element regions DA1, DA2, and DA3 are provided on the substrate 100.

A portion of the configuration of the memory cell array MA1 is provided in the element region DA1. For example, the global bit lines GBL, select transistors TR1, local bit lines LBL, memory cells MC, word lines WL, and select gate lines SG1 are provided in the element region DA1. On the upper surface of the substrate 100, a plurality of transistors used for transferring an operating voltage and the like, contacts and wiring for controlling the plurality of transistors, and the like are provided.

A portion of the structure of the memory cell array MA1 is provided in the element region DA2. For example, in the element region DA2, the wiring L2, the select transistors TR2, the wirings L3, and the select gate lines SG2 (FIG. 1) are provided. In the element region DA2, a plurality of transistors and the like used for transferring an operating voltage and the like are provided.

In the element region DA3, a plurality of transistors used for generating and transferring a control signal and the like, contacts and wirings for controlling the plurality of transistors, and the like are provided.

When implementing the control circuit CC2 (FIG. 16) (e.g., instead of the control circuit CC1), the element region DA2 may be omitted. When a transistor or the like used for generation of a control signal or the like is provided in the element region DA1, the element region DA3 may be omitted.

FIG. 27 is a schematic enlarged view of a region labelled “A” in FIG. 26. In FIG. 27, a depiction of some configurations such as the semiconductor layer 170 (FIG. 2) functioning as the diode D (FIG. 1) and the wiring 174 functioning as the wiring L1 (FIG. 2) are omitted.

In FIG. 27, a configuration of a portion of a plurality of wirings 110a to 110f corresponding to the word lines WL is shown.

A plurality of first portions 111a of the wiring 110a are arranged in the Y-direction. The end portions of the first portions 111a in the X-direction are commonly connected to the second portion 112a extending in the Y-direction.

The first portions 111b of the wiring 110b are provided between the first portions 111a of the wiring 110a adjacent in the Y-direction, respectively. The end portions of the first portions lllb in the X-direction are commonly connected to the second portion 112b extending in the Y-direction. The second portion 112b is connected to a third portion 113b extending in the X-direction. The third portion 113b is connected to the control circuit CC1 provided on the upper surface of the substrate 100 via contacts and wirings (not illustrated).

The wiring 110c has substantially the same configuration as the wiring 110b, and the first portion 111 and the second portion 112 of the wiring 110c are positioned on the lower side so as to overlap the first portion lllb and the second portion 112b of the wiring 110b when viewed from the Z direction. On the other hand, the wiring 110c includes a fourth portion 114c which does not overlap the wiring 110b when viewed from the Z-direction. The fourth portion 114c is connected to the control circuit CC1 provided on the upper surface of the substrate 100 via contacts 115, wirings 116, and the like.

The wirings 110d, 110e, and 110f are also configured in substantially the same manner as the wiring 110c, and are connected to the control circuit CC1 provided on the upper surface of the substrate 100 via fourth portions 114d, 114e, and 114f of the respective wirings 110d, 110e, and 110f, the contacts 115, the wirings 116, and the like.

Operating Voltage

Next, a preferable operating voltage in the memory cell arrays MA1 and MA2 will be described.

Operating Voltage in Reset Operation

In a reset operation, a reset voltage is applied to the selected memory cell MC to cause the selected memory cell MC to transition from a set state to a reset state. However, when the leakage current in the memory cell arrays MA1 and MA2 increases, a voltage drop in an internal resistance, a wiring resistance, and the like of the control circuits CC1 and CC2 may be significant, and a voltage applied to the selected memory cell MC decreases. When considering this point, for example, it is possible to perform a simulation as below.

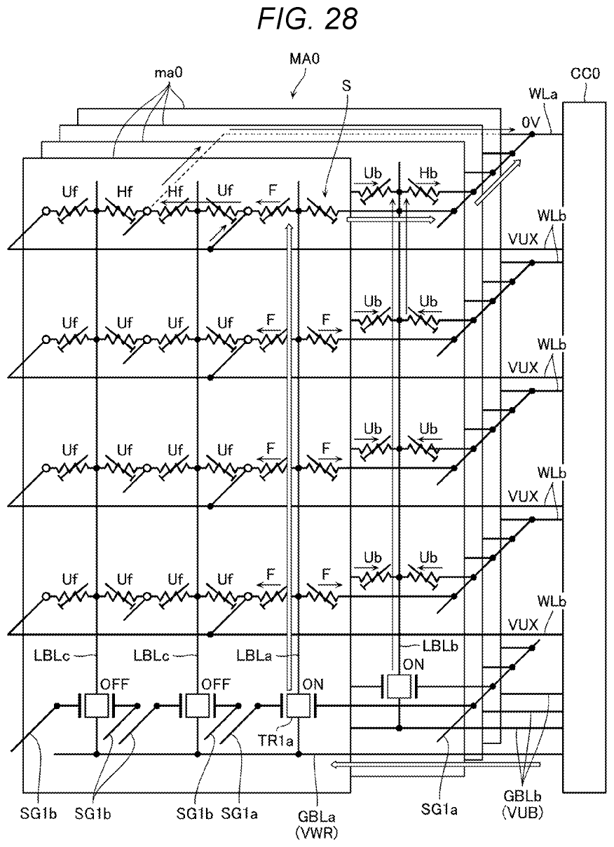

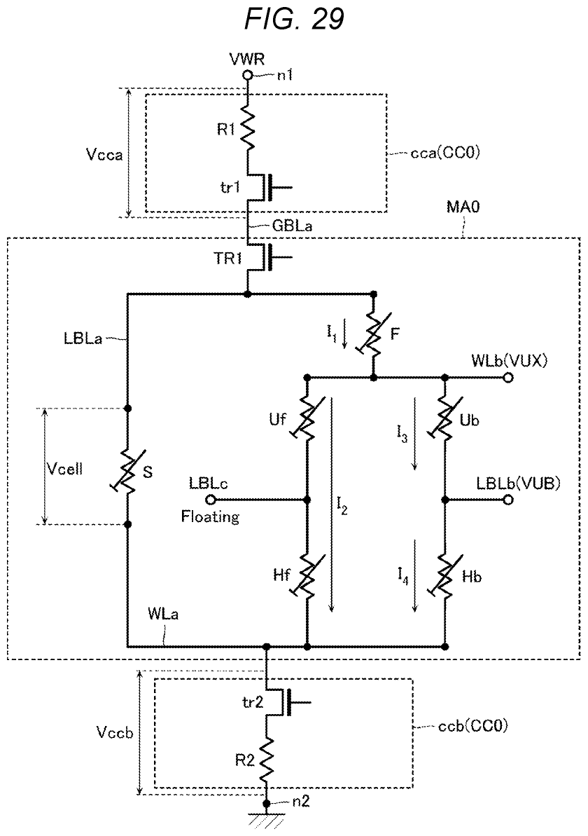

FIG. 28 and FIG. 29 are schematic equivalent circuit diagrams illustrating examples of models used for simulation of the operating voltage. In FIG. 28 and FIG. 29, a portion of the configuration may be omitted from the drawing.

As illustrated in FIG. 28, this model corresponds to the configuration according to the comparative example illustrated in FIG. 2, and includes a model corresponding to the memory cell array MA0 (comparative example) and a model corresponding to the control circuit CC0.

The model corresponding to the memory cell array MA0 is designed in consideration of the number of wirings, the number and type of elements, their connection relationships, current-voltage characteristics of respective elements, and variations thereof. The current-voltage characteristics of the element may be calculated from, for example, the constituent elements of the element, the material and film thickness of these constituent elements, and the like.

As illustrated in FIG. 29, the model corresponding to the control circuit CC0 includes a circuit element cca connected between a node n1 and the memory cell array MA0, a circuit element ccb connected between a node n2 and the memory cell array MA0.

The node n1 is, for example, a terminal whose voltage is set to a reset voltage VWR (second write voltage) and may be connected to a high potential side of a power supply voltage or an output terminal of a charge pump circuit, a step-up circuit, or a step-down circuit. The circuit element cca is a circuit element for transferring a voltage of the node n1 to the global bit line GBL, and includes a plurality of resistors and transistors connected between the node n1 and the memory cell array MA0. These resistors and transistors constitute a portion of, for example, a sense amplifier circuit, a multiplexer, or the like. R1 and tr1 in the figure schematically illustrate the plurality of resistors and transistors.

The node n2 is, for example, a terminal whose voltage is set to 0 V (first write voltage) and may be connected to a low potential side of the power supply voltage or the output of the charge pump circuit, the step-up circuit, or the step-down circuit. The circuit element ccb is a circuit element for transferring a voltage of the node n2 to the word line WL, and includes a plurality of resistors and transistors connected between the node n2 and the memory cell array MA0. These resistors and transistors form a portion of a word line switch, a word line driver, and the like, for example. R2 and tr2 in the figure schematically illustrate the plurality of resistors and transistors.

As shown in FIG. 28, hereinafter, the word line WL to which the first write voltage is applied may be referred to as a “selected word line WLa”, and the word line WL to which the non-select voltage is applied may be referred to as a “non-selected word line WLb”.

The global bit line GBL to which the second write voltage is applied may be referred to as a “selected global bit line GBLa” and the global bit line GBL to which the non-select voltage is applied may be referred to as a “non-selected global bit line GBLb”.

The local bit line LBL connected to the selected global bit line GBLa may be referred to as a “selected local bit line LBLa”, the local bit line LBL connected to the non-selected global bit line GBLb may be referred to as a “semi-selected local bit line LBLb”, and the local bit line LBL not connected to any global bit line GBL may be referred to as a “non-selected local bit line LBLc”.

Among the memory cells MC connected to the selected local bit line LBLa, those connected to the selected word line WLa may be referred to as a “selected memory cell S” and those connected to the non-selected word line WLb may be referred to as a “semi-selected memory cell F”. Among the memory cells MC connected to the semi-selected local bit line LBLb, those connected to the selected word line WLa may be referred to as a “semi-selected memory cells Hb” and those connected to the non-selected word lines WLb may be referred to as a “non-selected memory cell Ub”. Among the memory cells MC connected to the non-selected local bit line LBLc, those connected to the selected word line WLa may be referred to as a “semi-selected memory cells Hf” and those connected to the non-selected word lines WLb may be referred to as a “non-selected memory cell Uf”.

In the simulation, the leakage current when the reset operation is performed on the model illustrated in FIGS. 28 and 29 and a cell voltage Vcell applied to the selected memory cell S are calculated. Based on this, the relationship between a non-selected word line voltage VUX and the cell voltage Vcell and the like are calculated.

For example, an ON voltage is applied to a select gate line SG1a corresponding to the selected memory cell S to turn ON the plurality of select transistors TR1 connected to the select gate line SG1a. With this configuration, the selected local bit line LBLa and the semi-selected local bit line LBLb are connected to the global bit line GBL. Further, an OFF voltage is applied to the select gate lines SG1b other than select gate line SG1a to turn OFF the other select transistors TR1. With this configuration, the non-selected local bit line LBLc is in a floating state.

For example, the reset voltage VWR is transferred to the selected global bit line GBLa via the circuit element cca and the non-selected bit line voltage VUB is transferred to the non-selected global bit line GBLb. 0 V is transferred to the selected word line WLa via the circuit element ccb and a predetermined non-selected word line voltage VUX is transferred to the non-selected word line WLb other than selected word line WLa. With this configuration, the cell voltage Vcell is applied to the selected memory cell S.

Here, the reset voltage VWR is larger than the non-selected word line voltage VUX. Accordingly, as illustrated in FIG. 29, a leak current I1 flows between the selected local bit line LBLa and the non-selected word line WLb through the semi-selected memory cell F. The leakage current I1 may affect a voltage drop Vcca in the circuit element cca in some cases.

The non-selected word line voltage VUX is larger than 0 V. Accordingly, a leak current I2 flows between the non-selected word line WLb and the selected word line WLa through the non-selected memory cell Uf, the non-selected local bit line LBLc, and the semi-selected memory cell Hf. The leakage current I2 may affect a voltage drop Vccb in the circuit element ccb in some cases.

The non-selected word line voltage VUX is larger than the non-selected bit line voltage VUB. Accordingly, a leak current I3 flows between the non-selected word line WLb and the semi-selected local bit line LBLb through the non-selected memory cell Ub.

The non-selected bit line voltage VUB is larger than 0 V. Accordingly, a leakage current I4 flows between the semi-selected local bit line LBLb and the selected word line WLa through the semi-selected memory cell Hb. The leakage current I4 may affect the voltage drop Vccb in some cases. However, since the semi-selected local bit lines LBLb are fewer than the non-selected local bit lines LBLc, an influence of the leakage current is limited.

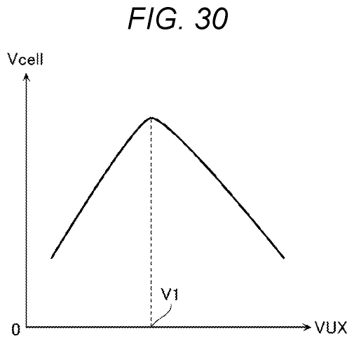

FIG. 30 is a schematic graph illustrating a result of the simulation. In the simulation, the non-selected word line voltage VUX is calculated so that the cell voltage Vcell becomes the maximum. In the following, such a non-selected word line voltage VUX is referred to as a “first voltage V1”. Also, a voltage of the non-selected local bit line LBLc when the non-selected word line voltage VUX is the first voltage V1 is referred to as a “second voltage V2”.

As illustrated in FIG. 30, in a case where the non-selected word line voltage VUX is smaller than the first voltage V1, the cell voltage Vcell is also smaller than the maximum value. This is considered to be due to, for example, the voltage drop Vcca or the like in the circuit element cca (see FIG. 29). Also, even when the non-selected word line voltage VUX is larger than the first voltage V1, the cell voltage Vcell is smaller than the maximum value. This is considered to be due to, for example, the voltage drop Vccb in the circuit element ccb or the like (see FIG. 29).

As described above, in the model illustrated in FIGS. 28 and 29, it is found that the cell voltage Vcell becomes the maximum value when the non-selected word line voltage VUX is set to the first voltage V1. In a certain configuration example, the first voltage V1 is approximately ⅔ times the reset voltage VWR and the second voltage V2 is approximately ⅓ times the reset voltage VWR.

Next, based on the result of such simulation, a preferable operating voltage in the reset operation of the semiconductor memory device including the memory cell arrays MA1 and MA2 will be described.

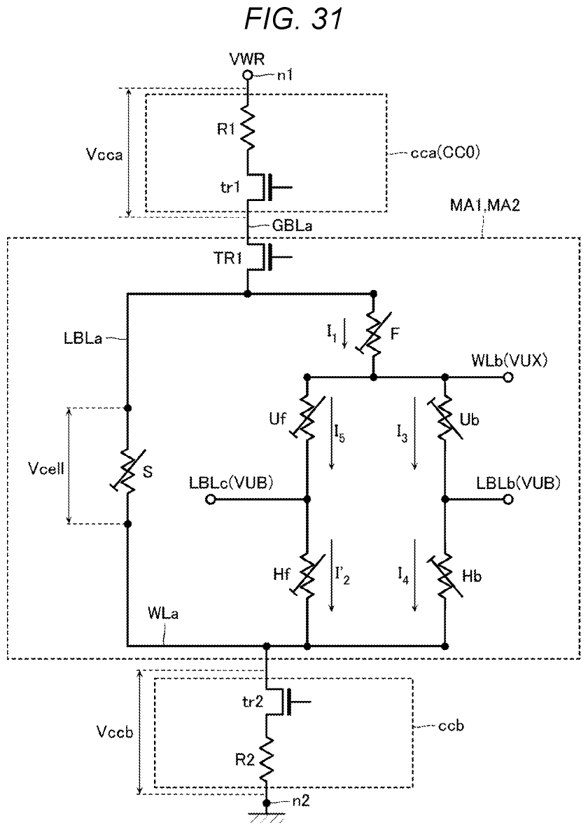

FIG. 31 is a schematic equivalent circuit diagram illustrating the configuration illustrated in FIG. 1 and FIG. 16 in a simplified manner, and corresponds to FIG. 29. In FIG. 31, a portion of the configuration may be omitted from the drawing.

As illustrated in FIG. 31, in the memory cell arrays MA1 and MA2, it is possible to apply the non-selected bit line voltage VUB to the non-selected local bit line LBLc.

In this case, a leak current I5 flows between non-selected word line WLb and semi-selected local bit line LBLb through the non-selected memory cell Uf. However, it is considered that the leakage current I5 little influence on the voltage drop Vcca in the circuit element cca and the voltage drop Vccb in the circuit element ccb.

A leak current I2′ flows between the non-selected local bit line LBLc and the selected word line WLa through the semi-selected memory cell Hf. The leakage current I2′ may affect the voltage drop Vccb in the circuit element ccb in some cases.

Here, as described above, in the memory cell arrays MA1 and MA2, it is possible to selectively and independently control the voltage of the non-selected local bit line LBLc and the voltage of the non-selected word line WLb. Accordingly, it is possible to decrease the voltage drop Vcca in the circuit element cca by increasing the non-selected word line voltage VUX, and to decrease the voltage drop Vccb in the circuit element ccb by decreasing the voltage of the non-selected local bit line LBLc. With this configuration, it is possible to increase the cell voltage Vcell as compared with the models illustrated in FIGS. 28 and 29. As a result, it is possible to provide a semiconductor memory device which operates at high speed.

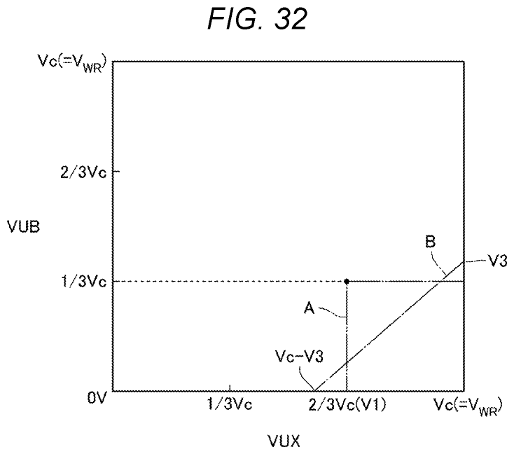

Next, preferred sizes of the non-selected word line voltage VUX and non-selected bit line voltage VUB will be described with reference to FIG. 32. FIG. 32 is a schematic graph illustrating the non-selected word line voltage VUX and the non-selected bit line voltage VUB. The horizontal axis of FIG. 32 illustrates the magnitude of the non-selected word line voltage VUX. The vertical axis of FIG. 32 illustrates the magnitude of the non-selected bit line voltage VUB.

The region A in FIG. 32 indicates a region where the non-selected word line voltage VUX is larger than the first voltage V1 and the non-selected bit line voltage VUB is smaller than the second voltage V2. In the first embodiment, for example, the magnitudes of the non-selected word line voltage VUX and the non-selected bit line voltage VUB may be set within the range of the region A. For example, when the first voltage V1 is approximately ⅔ VWR and the second voltage V2 is approximately ⅓ VWR, the non-selected word line voltage VUX may be set to approximately ¾ VWR and the non-selected bit line voltage VUB may be set to approximately ¼ VWR.

The region B in FIG. 32 indicates a region where an absolute value of the voltage applied to the non-selected memory cells Uf and Ub, that is, an absolute value of a difference between the non-selected word line voltage VUX and the non-selected bit line voltage VUB is equal to or greater than a third voltage V3. The third voltage V3 may be, for example, the same or substantially the same voltage as the read voltage applied to the selected memory cell MC in the read operation. When the magnitudes of the non-selected word line voltage VUX and the non-selected bit line voltage VUB are within the region B, a disturbance may occur in the non-selected memory cells Uf and Ub. That is, the non-selected memory cell Uf in the set state may be brought into the reset state, or the non-selected memory cell Ub in the reset state may be brought into the set state. Therefore, the magnitudes of the non-selected word line voltage VUX and the non-selected bit line voltage VUB may be set outside the range of the region B. The magnitudes of the non-selected word line voltage VUX and the non-selected bit line voltage VUB may be set on a straight line that defines the region B.

Operating Voltage in Set Operation

In the set operation, a set voltage is applied to the selected memory cell MC to cause the selected memory cell MC to transition from the reset state to the set state. Even when setting the operating voltage in the setting operation, it is possible to perform the simulation as described above.

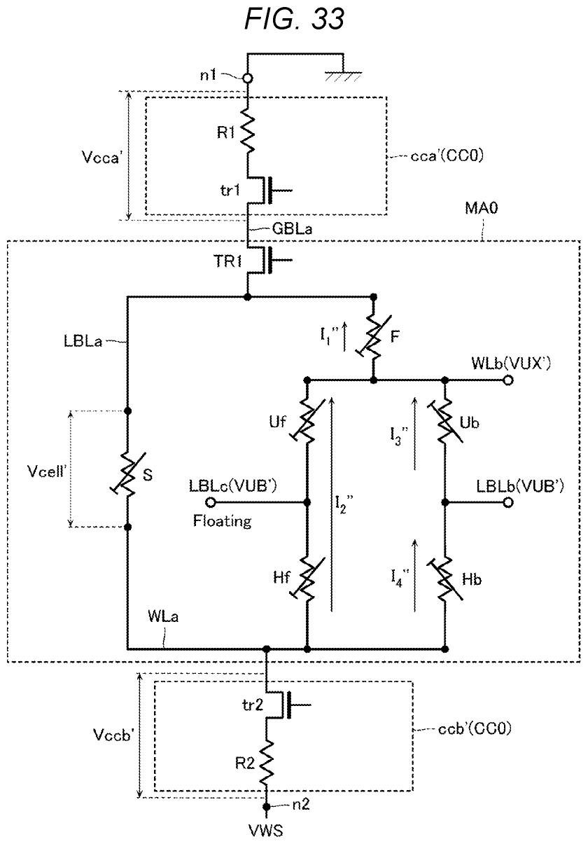

FIG. 33 is a schematic equivalent circuit diagram illustrating an example of a model used for simulation of the operating voltage. In FIG. 33, a portion of the configuration may be omitted from the drawing.

For simulation on the set operation, a model similar to the simulation on the reset operation is used. However, in the simulation on the set operation, the voltage of the node n1 is set to 0 V (second write voltage), and the voltage of the node n2 is set to a set voltage VWS (first write voltage). Accordingly, the circuit element cca′ and the circuit element ccb′ may have different configurations from the circuit element cca and the circuit element ccb from the connection relationship in the control circuit CC0.

The simulation on the set operation is performed in a similar manner as the simulation on the reset operation. However, a direction in which the voltage is applied to the selected memory cell S is reversed in the set operation and the reset operation. In the illustrated example, 0 V is transferred to the selected global bit line GBLa via the circuit element cca′, and the set voltage VWS is transferred to the selected word line WLa via the circuit element ccb′.

In the illustrated example, the set voltage VWS is larger than a non-selected bit line voltage VUB′, the non-selected bit line voltage VUB′ is larger than a non-selected word line voltage VUX′, and the non-selected word line voltage VUX′ is 0 V.

In the illustrated example, a voltage drop Vcca′ in the circuit element cca′ may be affected by a leakage current I1″ flowing between the selected local bit line LBLa and the non-selected word line WLb through the semi-selected memory cell F. In the illustrated example, the voltage drop Vccb′ in the circuit element ccb′ may be affected by a leakage current I2″ flowing through the non-selected memory cell Uf, the non-selected local bit line LBLc, and the semi-selected memory cell Hf, and the like.

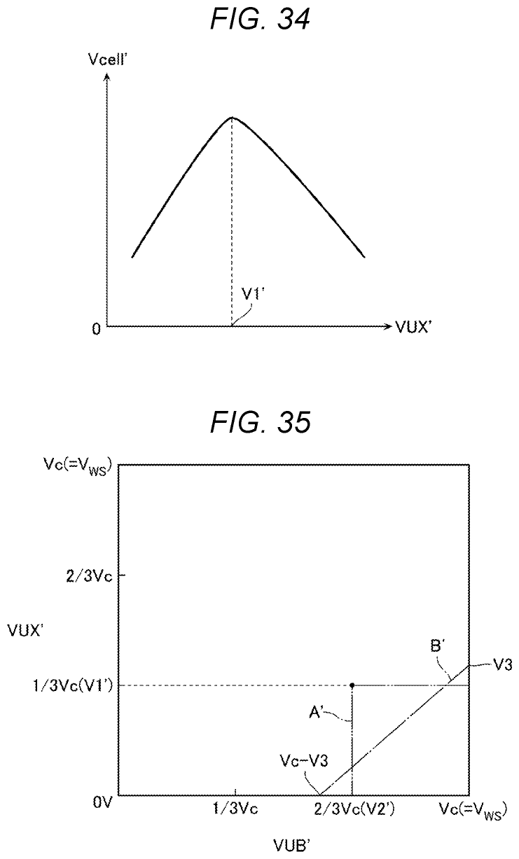

FIG. 34 is a schematic graph illustrating the results of the simulation. In the simulation, the non-selected word line voltage VUX′ at which a cell voltage Vcell′ becomes the maximum is calculated. In the following, such non-selected word line voltage VUX′ will be referred to as a “first voltage V1′”. The voltage of the non-selected local bit line LBLc when the non-selected word line voltage VUX′ is the first voltage V1′ is referred to as a “second voltage V2′”.

Next, preferred sizes of the non-selected word line voltage VUX′ and non-selected bit line voltage VUB′ will be described with reference to FIG. 35. FIG. 35 is a schematic graph illustrating the non-selected word line voltage VUX′ and the non-selected bit line voltage VUB′. The horizontal axis of FIG. 35 illustrates the magnitude of the non-selected bit line voltage VUB′. The vertical axis of FIG. 35 illustrates the magnitude of the non-selected word line voltage VUX′.

The region A′ in FIG. 35 indicates a region in which the non-selected word line voltage VUX′ is smaller than the first voltage V1′ and the non-selected bit line voltage VUB′ is larger than the second voltage V2′. In the first embodiment, the magnitudes of the non-selected word line voltage VUX′ and the non-selected bit line voltage VUB′ may be set within the range of the region A′. For example, when the first voltage V1′ is approximately ⅓ VWS and the second voltage V2′ is approximately ⅔ VWS, the non-selected word line voltage VUX′ is set to approximately ¼ VWR and the non-selected bit line voltage VUB is set to approximately ¾ VWR′.

The region B′ in FIG. 35 indicates a region in which an absolute value of the voltage applied to the non-selected memory cells Uf and Ub, that is, an absolute value of a difference between the non-selected word line voltage VUX′ and the non-selected bit line voltage VUB is equal to or greater than the third voltage V3. When the magnitudes of the non-selected word line voltage VUX′ and the non-selected bit line voltage VUB′ are within the region B′, disturbance may occur in the non-selected memory cells Uf and Ub. Accordingly, in the first embodiment, the magnitudes of the non-selected word line voltage VUX′ and the non-selected bit line voltage VUB′ may be set outside the range of the region B′. The magnitudes of the non-selected word line voltage VUX′ and the non-selected bit line voltage VUB′ may be set on a straight line that defines the region B′.

### OTHER EMBODIMENTS

The configurations described above are presented as examples, and specific configurations may be appropriately modified. For example, as described with reference to FIG. 1, the first memory cell array MA1 includes the diode D connected to the local bit line LBL. However, instead of the diode D, other nonlinear elements may be used. Such a nonlinear element may include, for example, a nonlinear element having a Schottky junction composed of a combination of a metal layer and a semiconductor layer or the like. For example, a nonlinear element using a property such as chalcogenide containing chalcogen may be available. Further, for example, a nonlinear element including two kinds of conductive layers (metals or semiconductors) having different conduction band energy bands and an insulating layer (tunnel insulating layer) provided between these conductive layers may be implemented.

In the examples described above, in the reset operation, the voltage of the first polarity with which the voltage of the selected local bit line LBLa becomes larger than the voltage of the selected word line WLa is applied to the selected memory cell S. In the set operation, a voltage of the second polarity opposite to the first polarity is applied. However, there may be a case where the voltage of the second polarity is applied to the selected memory cell S in the reset operation and the voltage of the first polarity is applied to the selected memory cell S in the set operation.

The operating voltage during the reset operation and the operating voltage during the setting operation may be appropriately adjusted. For example, when the resistance change film 130 has characteristics tolerant of disturbance, the non-selected word line voltage VUX and the non-selected bit line voltage VUB, and the non-selected word line voltage VUX′ and the non-selected bit line voltage VUB′ may be set in the region B (FIG. 32) or the region B′ (FIG. 35).

[Remarks]

The present disclosure provides for the following embodiments, amongst others.

### Embodiment 1

A semiconductor memory device including:

a substrate;

a plurality of first wirings arranged in a first direction intersecting with a surface of the substrate;

a second wiring extending in the first direction;

a resistance change film provided between the first wiring and the second wiring;

a third wiring which is closer to the substrate than the second wiring and extends in a second direction intersecting with the first direction;

a first semiconductor layer provided between the second wiring and the third wiring and connected to the second wiring and the third wiring;

a first electrode facing the first semiconductor layer;

a fourth wiring which is farther from the substrate than the second wiring, is connected to the second wiring, and extends in a third direction intersecting with the first direction;

a fifth wiring provided between the fourth wiring and the substrate, extending in the first direction, and connected to the fourth wiring;

a sixth wiring provided between the fifth wiring and the substrate;

a second semiconductor layer provided between the fifth wiring and the sixth wiring and connected to the fifth wiring and the sixth wiring; and

a second electrode facing the second semiconductor layer.

### Embodiment 2

The semiconductor memory device according to embodiment 1, further including a nonlinear element provided between the second wiring and the fourth wiring and connected to the second wiring and the fourth wiring.

### Embodiment 3

The semiconductor memory device according to embodiment 1, in which the semiconductor memory device includes

a plurality of the second wirings arranged in the second direction,

a plurality of the first semiconductor layers arranged in the second direction and connected to the plurality of second wirings and the third wiring,

a plurality of the first electrodes arranged in the second direction and facing the plurality of first semiconductor layers,

a plurality of the fourth wirings arranged in the second direction and connected to the plurality of the second wirings,

a plurality of the fifth wirings arranged in the second direction and connected to the plurality of fourth wirings, and

a plurality of the second wirings arranged in the second direction and connected to the plurality of fifth wirings and the sixth wiring.

### Embodiment 4

The semiconductor memory device according to embodiment 1, in which the semiconductor memory device includes

a plurality of the second wirings arranged in the third direction and connected to the fourth wiring,

a plurality of the first semiconductor layers arranged in the third direction and connected to the plurality of second wirings,

a plurality of the third wirings arranged in the third direction and connected to the plurality of first semiconductor layers.

### Embodiment 5

The semiconductor memory device according to embodiment 3, further including:

a control circuit connected to the plurality of first wirings, the third wiring, and the sixth wiring,

in which, when a voltage to be transferred to one of the plurality of first wirings is set to a first write voltage, a voltage to be transferred to the plurality of other first wirings is set to a non-select voltage, a voltage to be transferred to one of the plurality of second wirings is set to a second write voltage, and the plurality of other second wirings are set in a floating state, and the non-select voltage when an absolute value of a difference between a voltage of the first wiring to which the first write voltage is transferred and a voltage of the second wiring to which the second write voltage is transferred becomes the maximum is set as a first voltage,

the control circuit applies a voltage that coincides with or substantially coincides with the first write voltage to at least one of the plurality of first wirings and applies a first operating voltage having a magnitude between the second write voltage and the first voltage to at least one of the plurality of first wirings.

### Embodiment 6

The semiconductor memory device according to embodiment 5,

in which the control circuit applies the first operating voltage to at least two of the plurality of first wirings.

### Embodiment 7

The semiconductor memory device according to embodiment 5,

in which, when a voltage to be transferred to one of the plurality of first wirings is set to the first write voltage, a voltage to be transferred to the plurality of other first wirings is set to the first voltage, a voltage to be transferred to one of the plurality of second wirings is set to the second write voltage, and the plurality of other second wirings are set in a floating state, and the voltage of the second wirings is set as a second voltage,

the control circuit applies a second operating voltage having a magnitude between the first write voltage and the second voltage to the sixth wiring.

### Embodiment 8

The semiconductor memory device according to embodiment 7,

in which the control circuit, in a read operation, applies a read voltage between at least one of the plurality of first wirings and the third wiring, and

an absolute value of a difference between the first and second operating voltages is smaller than the read voltage.

### Embodiment 9

A semiconductor memory device including:

a substrate;

a plurality of first wirings arranged in a first direction intersecting with a surface of the substrate and including a portion extending in a second direction intersecting with the first direction;

a plurality of second wirings arranged in the second direction and extending in the first direction;

a resistance change film provided between the portion of the first wiring extending in the second direction and the second wiring;

a plurality of third wirings which are closer to the substrate than the plurality of second wirings and are arranged in the second direction;

a plurality of first semiconductor layers provided between the plurality of second wirings and the plurality of third wirings, arranged in the second direction, and connected to the plurality of second wirings and the plurality of third wirings;

a first electrode extending in the second direction and facing the first semiconductor layer;

a plurality of fourth wirings which are farther from the substrate than the plurality of second wirings and arranged in the second direction;

a plurality of second semiconductor layers provided between the plurality of second wirings and the plurality of fourth wirings, arranged in the second direction, and connected to the plurality of second wirings and the plurality of fourth wirings;

a second electrode extending in the second direction and facing the second semiconductor layer; and

a control circuit connected to the plurality of first wirings, the plurality of third wirings, and the plurality of fourth wirings;

in which the control circuit is configured so that

a first operating voltage can be applied to at least one of the plurality of third wirings and a second operating voltage different from the first operating voltage can be applied to at least one other third wiring, and

a third operating voltage can be applied to the fourth wiring corresponding to the third wiring to which the first operating voltage is applied and a fourth operating voltage different from the third operating voltage can be applied to the fourth wiring corresponding to the third wiring to which the second operating voltage is applied.

### Embodiment 10

The semiconductor memory device according to embodiment 9,

in which the control circuit, in a write operation,

applies the third operating voltage to one of the plurality of fourth wirings,

applies the fourth operating voltage to other one of the fourth wirings,

applies the first operating voltage to the third wiring corresponding to the fourth wiring to which the third operating voltage is applied, and

applies the second operating voltage to the third wiring corresponding to the fourth wiring to which the fourth operating voltage is applied, and

the third operating voltage is larger than the fourth operating voltage and the first operating voltage is larger than the second operating voltage.

### Embodiment 11

The semiconductor memory device according to embodiment 9,

in which the plurality of the second wirings is further arranged in a third direction intersecting with the first direction and the second direction,

the plurality of first semiconductor layers is further arranged in the third direction and connected to the plurality of second wirings and the plurality of third wirings,

the plurality of second semiconductor layers is further arranged in the third direction and connected to the plurality of second wirings and the plurality of fourth wirings, and the semiconductor memory device further includes:

a plurality of the first electrodes arranged in the third direction and facing the plurality of first semiconductor layers, and

a plurality of the second electrodes arranged in the third direction and facing the plurality of second semiconductor layers.

### Embodiment 12

The semiconductor memory device according to embodiment 11, further including:

a control circuit connected to the plurality of first wirings, the third wiring, and the fourth wiring,

in which, when a voltage to be transferred to one of the plurality of first wirings is set to a first write voltage, a voltage to be transferred to the plurality of other first wirings is set to a non-select voltage, a voltage to be transferred to one of the plurality of second wirings is set to a second write voltage, and the plurality of other second wirings are set in a floating state, and the non-select voltage when an absolute value of a difference between a voltage of the first wiring to which the first write voltage is transferred and a voltage of the second wiring to which the second write voltage is transferred becomes the maximum is set as a first voltage,

the control circuit applies a voltage that coincides with or substantially coincides with the first write voltage to at least one of the plurality of first wirings and applies a fifth operating voltage having a magnitude between the second write voltage and the first voltage to at least one of the plurality of first wirings.

### Embodiment 13

The semiconductor memory device according to embodiment 12, in which the control circuit applies the fifth operating voltage to at least two of the plurality of first wirings.

### Embodiment 14

The semiconductor memory device according to embodiment 12, in which when a voltage to be transferred to one of the plurality of first wirings is set to the first write voltage, a voltage to be transferred to the plurality of other first wirings is set to the first voltage, a voltage to be transferred to one of the plurality of second wirings is set to the second write voltage, and the plurality of other second wirings are set in a floating state, and the voltage of the second wirings is set as a second voltage, the control circuit applies a sixth operating voltage having a magnitude between the first write voltage and the second voltage to at least one of the plurality of fourth wirings.

### Embodiment 15

The semiconductor memory device according to embodiment 14,

in which the control circuit, in a read operation, applies a read voltage between at least one of the plurality of first wirings and at least one of the plurality of third wirings, and

an absolute value of a difference between the fifth and sixth operating voltages is smaller than the read voltage.

### Embodiment 16

A semiconductor memory device including:

a substrate;

a plurality of first wirings arranged in a first direction intersecting with a surface of the substrate;

a plurality of second wirings arranged in a second direction intersecting with the first direction and extending in the first direction;

a resistance change film provided between the first wiring and the second wiring;

a third wiring which is closer to the substrate than the plurality of second wirings and extends in the second direction;

a plurality of first semiconductor layers provided between the plurality of second wirings and the third wiring and connected to the plurality of second wirings and the third wiring;

a plurality of first electrodes arranged in the second direction and facing the plurality of first semiconductor layers;

a plurality of second semiconductor layers electrically connected to the plurality of second wirings;

one or a plurality of fourth wirings connected to the plurality of second semiconductor layers;

a plurality of second electrodes facing the plurality of second semiconductor layers; and

a control circuit connected to the plurality of first wirings, the third wiring, and the one or plurality of fourth wirings,

in which, when a voltage to be transferred to one of the plurality of first wirings is set to a first write voltage, a voltage to be transferred to the plurality of other first wirings is set to a non-select voltage, a voltage to be transferred to one of the plurality of second wirings is set to a second write voltage, and the plurality of other second wirings are set in a floating state, if a non-select voltage when an absolute value of a difference between a voltage of the first wiring to which the first write voltage is transferred and a voltage of the second wiring to which the second write voltage is transferred becomes the maximum is set as a first voltage, the control circuit applies a voltage that coincides with or substantially coincides with the first write voltage to at least one of the plurality of first wirings and applies a first operating voltage having a magnitude between the second write voltage and the first voltage to at least one of the plurality of first wirings.

### Embodiment 17

The semiconductor memory device according to embodiment 16,

in which the control circuit applies the first operating voltage to at least two of the plurality of first wirings.

### Embodiment 18

The semiconductor memory device according to embodiment 16,

in which when a voltage to be transferred to one of the plurality of first wirings is set to the first write voltage, a voltage to be transferred to the plurality of other first wirings is set to the first voltage, a voltage to be transferred to one of the plurality of second wirings is set to the second write voltage, and the plurality of other second wirings are set in a floating state, and the voltage of the second wirings is set as a second voltage, the control circuit applies a second operating voltage having a magnitude between the first write voltage and the second voltage to the fourth wiring.

### Embodiment 19

The semiconductor memory device according to embodiment 18, in which the control circuit, in a read operation, applies a read voltage between at least one of the plurality of first wirings and the third wiring, and an absolute value of a difference between the first and second operating voltages is smaller than the read voltage.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A semiconductor memory device comprising:
a substrate;
a plurality of first wirings arranged in a first direction intersecting with a surface of the substrate;
a second wiring extending in the first direction;
a resistance change film provided between the first wiring and the second wiring;
a third wiring which is closer to the substrate than the second wiring and extends in a second direction intersecting with the first direction;
a first semiconductor layer provided between the second wiring and the third wiring and connected to the second wiring and the third wiring;
a first electrode facing the first semiconductor layer;
a fourth wiring which is farther from the substrate than the second wiring, is connected to the second wiring, and extends in a third direction intersecting with the first direction;
a fifth wiring provided between the fourth wiring and the substrate, extending in the first direction, and connected to the fourth wiring;
a sixth wiring provided between the fifth wiring and the substrate;
a second semiconductor layer provided between the fifth wiring and the sixth wiring and connected to the fifth wiring and the sixth wiring; and
a second electrode facing the second semiconductor layer.

2. The semiconductor memory device according to claim 1, further comprising:
a nonlinear element provided between the second wiring and the fourth wiring and connected to the second wiring and the fourth wiring.

3. The semiconductor memory device according to claim 1, in which the semiconductor memory device comprises:
a plurality of the second wirings arranged in the second direction,
a plurality of the first semiconductor layers arranged in the second direction and connected to the plurality of second wirings and the third wiring,
a plurality of the first electrodes arranged in the second direction and facing the plurality of first semiconductor layers,
a plurality of the fourth wirings arranged in the second direction and connected to the plurality of the second wirings,
a plurality of the fifth wirings arranged in the second direction and connected to the plurality of fourth wirings, and
a plurality of the second wirings arranged in the second direction and connected to the plurality of fifth wirings and the sixth wiring.

4. The semiconductor memory device according to claim 1, in which the semiconductor memory device includes
a plurality of the second wirings arranged in the third direction and connected to the fourth wiring,
a plurality of the first semiconductor layers arranged in the third direction and connected to the plurality of second wirings,
a plurality of the third wirings arranged in the third direction and connected to the plurality of first semiconductor layers.

5. The semiconductor memory device according to claim 3, further including:
a control circuit connected to the plurality of first wirings, the third wiring, and the sixth wiring,
wherein the semiconductor memory device is configured such that, when a voltage to be transferred to one of the plurality of first wirings is set to a first write voltage, a voltage to be transferred to the plurality of other first wirings is set to a non-select voltage, a voltage to be transferred to one of the plurality of second wirings is set to a second write voltage, and the plurality of other second wirings are set in a floating state, and the non-select voltage when an absolute value of a difference between a voltage of the first wiring to which the first write voltage is transferred and a voltage of the second wiring to which the second write voltage is transferred becomes the maximum is set as a first voltage,
the control circuit applies a voltage that coincides with the first write voltage to at least one of the plurality of first wirings and applies a first operating voltage having a magnitude between the second write voltage and the first voltage to at least one of the plurality of first wirings.

6. The semiconductor memory device according to claim 5,
wherein the control circuit is configured to apply the first operating voltage to at least two of the plurality of first wirings.

7. The semiconductor memory device according to claim 5,
wherein the semiconductor memory device is configured such that, when a voltage to be transferred to one of the plurality of first wirings is set to the first write voltage, a voltage to be transferred to the plurality of other first wirings is set to the first voltage, a voltage to be transferred to one of the plurality of second wirings is set to the second write voltage, and the plurality of other second wirings are set in a floating state, and the voltage of the second wirings is set as a second voltage,
the control circuit applies a second operating voltage having a magnitude between the first write voltage and the second voltage to the sixth wiring.

8. The semiconductor memory device according to claim 7,
wherein the control circuit is configured to apply, in a read operation, a read voltage between at least one of the plurality of first wirings and the third wiring, and
an absolute value of a difference between the first and second operating voltages is smaller than the read voltage.

9. A semiconductor memory device comprising:
a substrate;
a plurality of first wirings arranged in a first direction intersecting with a surface of the substrate and including a portion extending in a second direction intersecting with the first direction;
a plurality of second wirings arranged in the second direction and extending in the first direction;
a resistance change film provided between the portion of the first wiring extending in the second direction and the second wiring;
a plurality of third wirings which are closer to the substrate than the plurality of second wirings and are arranged in the second direction;
a plurality of first semiconductor layers provided between the plurality of second wirings and the plurality of third wirings, arranged in the second direction, and connected to the plurality of second wirings and the plurality of third wirings;
a first electrode extending in the second direction and facing the first semiconductor layer;
a plurality of fourth wirings which are farther from the substrate than the plurality of second wirings and arranged in the second direction;
a plurality of second semiconductor layers provided between the plurality of second wirings and the plurality of fourth wirings, arranged in the second direction, and connected to the plurality of second wirings and the plurality of fourth wirings;
a second electrode extending in the second direction and facing the second semiconductor layer; and
a control circuit connected to the plurality of first wirings, the plurality of third wirings, and the plurality of fourth wirings;
wherein the control circuit is configured to apply a first operating voltage to at least one of the plurality of third wirings, and to apply a second operating voltage different from the first operating voltage to at least one other third wiring, and
to apply a third operating voltage to a fourth wiring of the plurality of fourth wirings corresponding to the third wiring to which the first operating voltage is applied, and to apply a fourth operating voltage different from the third operating voltage to a fourth wiring of the plurality of fourth wirings corresponding to the third wiring to which the second operating voltage is applied.

10. The semiconductor memory device according to claim 9, wherein the control circuit is configured to apply, in a write operation,
the third operating voltage to one of the plurality of fourth wirings,
the fourth operating voltage to an other one of the fourth wirings,
the first operating voltage to a third wiring of the plurality of third wirings corresponding to the fourth wiring to which the third operating voltage is applied, and
the second operating voltage to a third wiring of the plurality of third wirings corresponding to the fourth wiring to which the fourth operating voltage is applied, and
the third operating voltage is larger than the fourth operating voltage and the first operating voltage is larger than the second operating voltage.

11. The semiconductor memory device according to claim 9, wherein
the plurality of the second wirings is further arranged in a third direction intersecting with the first direction and the second direction,
the plurality of first semiconductor layers is further arranged in the third direction and connected to the plurality of second wirings and the plurality of third wirings,
the plurality of second semiconductor layers is further arranged in the third direction and connected to the plurality of second wirings and the plurality of fourth wirings, and the semiconductor memory device further comprises:
a plurality of the first electrodes arranged in the third direction and facing the plurality of first semiconductor layers; and
a plurality of the second electrodes arranged in the third direction and facing the plurality of second semiconductor layers.

12. The semiconductor memory device according to claim 11, wherein the control circuit is configured such that, when a voltage to be transferred to one of the plurality of first wirings is set to a first write voltage, a voltage to be transferred to the plurality of other first wirings is set to a non-select voltage, a voltage to be transferred to one of the plurality of second wirings is set to a second write voltage, and the plurality of other second wirings are set in a floating state, and the non-select voltage when an absolute value of a difference between a voltage of the first wiring to which the first write voltage is transferred and a voltage of the second wiring to which the second write voltage is transferred becomes the maximum is set as a first voltage,
the control circuit applies a voltage that coincides with the first write voltage to at least one of the plurality of first wirings and applies a fifth operating voltage having a magnitude between the second write voltage and the first voltage to at least one of the plurality of first wirings.

13. The semiconductor memory device according to claim 12,
wherein the control circuit is configured to apply the fifth operating voltage to at least two of the plurality of first wirings.

14. The semiconductor memory device according to claim 12,
wherein the control circuit is configured such that, when a voltage to be transferred to one of the plurality of first wirings is set to the first write voltage, a voltage to be transferred to the plurality of other first wirings is set to the first voltage, a voltage to be transferred to one of the plurality of second wirings is set to the second write voltage, and the plurality of other second wirings are set in a floating state, and the voltage of the second wirings is set as a second voltage, the control circuit applies a sixth operating voltage having a magnitude between the first write voltage and the second voltage to at least one of the plurality of fourth wirings.

15. The semiconductor memory device according to claim 14,
wherein the control circuit is configured to apply, in a read operation, a read voltage between at least one of the plurality of first wirings and at least one of the plurality of third wirings, and
an absolute value of a difference between the fifth and sixth operating voltages is smaller than the read voltage.

16. A semiconductor memory device comprising:
a substrate;
a plurality of first wirings arranged in a first direction intersecting with a surface of the substrate;
a plurality of second wirings arranged in a second direction intersecting with the first direction and extending in the first direction;
a resistance change film provided between the first wiring and the second wiring;
a third wiring which is closer to the substrate than the plurality of second wirings and extends in the second direction;
a plurality of first semiconductor layers provided between the plurality of second wirings and the third wiring and connected to the plurality of second wirings and the third wiring;
a plurality of first electrodes arranged in the second direction and facing the plurality of first semiconductor layers;
a plurality of second semiconductor layers electrically connected to the plurality of second wirings;
one or a plurality of fourth wirings connected to the plurality of second semiconductor layers;
a plurality of second electrodes facing the plurality of second semiconductor layers; and
a control circuit connected to the plurality of first wirings, the third wiring, and the one or plurality of fourth wirings,
wherein the control circuit is configured such that, when a voltage to be transferred to one of the plurality of first wirings is set to a first write voltage, a voltage to be transferred to the plurality of other first wirings is set to a non-select voltage, a voltage to be transferred to one of the plurality of second wirings is set to a second write voltage, and the plurality of other second wirings are set in a floating state, and a non-select voltage when an absolute value of a difference between a voltage of the first wiring to which the first write voltage is transferred and a voltage of the second wiring to which the second write voltage is transferred becomes a maximum is set as a first voltage,
the control circuit applies a voltage that coincides with the first write voltage to at least one of the plurality of first wirings and
applies a voltage having a magnitude between the second write voltage and the first voltage to at least one of the plurality of first wirings.

17. The semiconductor memory device according to claim 16,
wherein the control circuit is configured to apply the first operating voltage to at least two of the plurality of first wirings.

18. The semiconductor memory device according to claim 16,
wherein the control circuit is configured such that when a voltage to be transferred to one of the plurality of first wirings is set to the first write voltage, a voltage to be transferred to the plurality of other first wirings is set to the first voltage, a voltage to be transferred to one of the plurality of second wirings is set to the second write voltage, and the plurality of other second wirings are set in a floating state, and the voltage of the second wirings is set as a second voltage, the control circuit applies a second operating voltage having a magnitude between the first write voltage and the second voltage to the fourth wiring.

19. The semiconductor memory device according to claim 18,
wherein the control circuit is configured to apply, in a read operation, a read voltage between at least one of the plurality of first wirings and the third wiring, and
an absolute value of a difference between the first and second operating voltages is smaller than the read voltage.
